(19) United States
(12) Patent Application Publication
(10) Pub. No.: US 2014/0085829 A1
(43) Pub. Date: Mar. 27, 2014

(54) MULTI-LAYERED BOARD AND SEMICONDUCTOR PACKAGE

(71) Applicant: Fujifilm Corporation, Tokyo (JP)

(72) Inventor: Kosuke YAMASHITA, Haibara-gun (JP)

(73) Assignee: Fujifilm Corporation, Tokyo (JP)

(21) Appl. No.: 14/030,148

(22) Filed: Sep. 18, 2013

(30) Foreign Application Priority Data
Sep. 26, 2012 (JP) 2012-212545
May 16, 2013 (JP) 2013-103819

(51) Int. Cl. H05K 1/02

(52) U.S. Cl. CPC H05K 1/0204
USPC 361/717; 174/252

(57) ABSTRACT

The invention provides a multi-layered board and a semiconductor package including the multi-layered board with improved heat dissipation performance of the semiconductor package. A multi-layered board includes an anisotropically-conductive member that includes an insulating base which is an anodized film of an aluminum substrate and in which through-holes are formed in a thickness direction and a plurality of conduction passages which are formed of a conductive material filled in the through-holes and which extend through the insulating base in the thickness direction with the conduction passages insulated from each other, a heat conducting layer that includes heat conducting portions and is disposed on at least one surface of the anisotropically-conductive member, and heat dissipating portions formed of the conductive material and protruding from the insulating base.

### BACKGROUND OF THE INVENTION

The present invention relates to a multi-layered board including an anisotropically-conductive member and a semiconductor package using the multi-layered board.

A three-dimensional mounting technique is known for being a trend of semiconductor mounting techniques. By employing this technique, even a semiconductor device manufactured using design rules of former generations can exhibit the same performance as the newest semiconductor devices and a data transmission rate between different types of semiconductor devices can be raised.

As an application example of the three-dimensional mounting technique, a configuration in which an IC chip (semiconductor device) and an anisotropically-conductive film (anisotropically-conductive member) are alternately superimposed is disclosed in FIG. 6 of JP 2009-164095 A.

### SUMMARY OF THE INVENTION

Thermal conductivity of an insulating base constituting the anisotropically-conductive member is low, and particularly, in a semiconductor package having semiconductor devices disposed on both surfaces of the anisotropically-conductive member such as a three-dimensional mounting type, heat generated from the semiconductor devices is likely to be confined in the semiconductor package.

The present invention is made in consideration of the above-mentioned circumstances and an object thereof is to improve heat dissipation performance of a semiconductor package manufactured using an anisotropically-conductive member.

The inventors of the present invention found that it is possible to improve heat dissipation performance by using a specific multi-layered board as an anisotropically-conductive member used in a semiconductor package, and thus accomplished the present invention.

That is, the present invention provides the following configurations (1) to (7).

(1) A multi-layered board comprising an anisotropically-conductive member that comprises an insulating base which is an anodized film of an aluminum substrate and in which through-holes are formed in a thickness direction and a plurality of conduction passages which are formed of a conductive material filled in the through-holes and which extend through the insulating base in the thickness direction with the conduction passages insulated from each other, a heat conducting layer that comprises heat conducting portions and is disposed on at least one surface of the anisotropically-conductive member, and heat dissipating portions formed of the conductive material and protruding from the insulating base.
(2) The multi-layered board according to (1), wherein the heat conducting layer comprises the heat conducting portions, interconnecting portions formed of a conductive material, and insulating portions insulating the heat conducting portions and the interconnecting portions from each other.
(3) The multi-layered board according to (2), wherein the insulating portions are formed of a resin.
(4) The multi-layered board according to any one of (1) to (3), wherein the heat dissipating portions protruding from the anodized film have a height of 35 μm or more.
(5) The multi-layered board according to any one of (1) to (4), wherein the heat conducting portions are embedded in the anodized film.
(6) The multi-layered board according to any one of (1) to (5), wherein the heat conducting layer is disposed between two or more anisotropically-conductive members.
(7) A semiconductor package comprising the multi-layered board according to any one of (1) to (6), and a semiconductor device that is disposed on at least one surface of the multi-layered board.

According to the present invention, it is possible to improve heat dissipation performance of a semiconductor package manufactured using an anisotropically-conductive member.

### BRIEF DESCRIPTION OF THE DRAWINGS

FIG. 1A is a plan view schematically illustrating a multi-layered board according to a first embodiment, FIG. 1B is a bottom view thereof, and FIG. 1C is a cross-sectional view taken along line A-A′ of FIG. 1A and line A-A′ of FIG. 1B.

FIG. 2 is a cross-sectional view schematically illustrating a semiconductor package employing the multi-layered board according to the first embodiment.

FIG. 3A is a plan view schematically illustrating a semiconductor package according to a second embodiment in which a semiconductor device is omitted and FIG. 3B is a cross-sectional view taken along line B-B′ of FIG. 3A.

FIG. 4 is a schematic diagram illustrating a semiconductor package according to a third embodiment.

FIG. 5 is a cross-sectional view schematically illustrating a semiconductor package according to a fourth embodiment.

FIG. 6 is a cross-sectional view schematically illustrating a semiconductor package according to a fifth embodiment.

FIG. 7 is a cross-sectional view schematically illustrating a semiconductor package according to a sixth embodiment.

FIGS. 8A to 8D are cross-sectional views schematically illustrating a method of manufacturing the anisotropically-conductive members according to the first and second embodiments and the fourth to sixth embodiments.

FIGS. 9A to 9F are cross-sectional views schematically illustrating a method (Method 1) of manufacturing the anisotropically-conductive member according to the third embodiment.

FIGS. 10A to 10G are cross-sectional views schematically illustrating a method (Method 2) of manufacturing the anisotropically-conductive member according to the third embodiment.

FIGS. 11A to 11F are cross-sectional views schematically illustrating a method (Method 3) of manufacturing the anisotropically-conductive member according to the third embodiment.

FIGS. 12A to 12G are cross-sectional views schematically illustrating a method (Method 4) of manufacturing the anisotropically-conductive member according to the third embodiment.

FIGS. 13A to 13E are cross-sectional views schematically illustrating a method (Method 5) of manufacturing the anisotropically-conductive member according to the third embodiment.

FIGS. 14A to 14D are cross-sectional views schematically illustrating a method (Method 6) of manufacturing the anisotropically-conductive member according to the third embodiment.

FIGS. 15A to 15D are cross-sectional views schematically illustrating a method (Method 7) of manufacturing the anisotropically-conductive member according to the third embodiment.

FIGS. 16A to 16E are cross-sectional views schematically illustrating a method (Method 8) of manufacturing the anisotropically-conductive member according to the third embodiment.

### DETAILED DESCRIPTION OF THE INVENTION

A multi-layered board according to the present invention comprises an anisotropically-conductive member having an insulating base which is an anodized film of an aluminum substrate and in which through-holes are formed in a thickness direction and a plurality of conduction passages which are formed of a conductive material filled in the through-holes and which extend through the insulating base in the thickness direction in a state where the conduction passages are insulated from each other, a heat conducting layer having heat conducting portions and disposed on at least one surface of the anisotropically-conductive member, and heat dissipating portions formed of the conductive material and protruding from the insulating base.

A semiconductor package according to the present invention comprises the multi-layered board according to the present invention and a semiconductor device disposed on at least one surface of the multi-layered board.

Hereinafter, embodiments of the present invention will be described.

### First Embodiment

### Multi-Layered Board

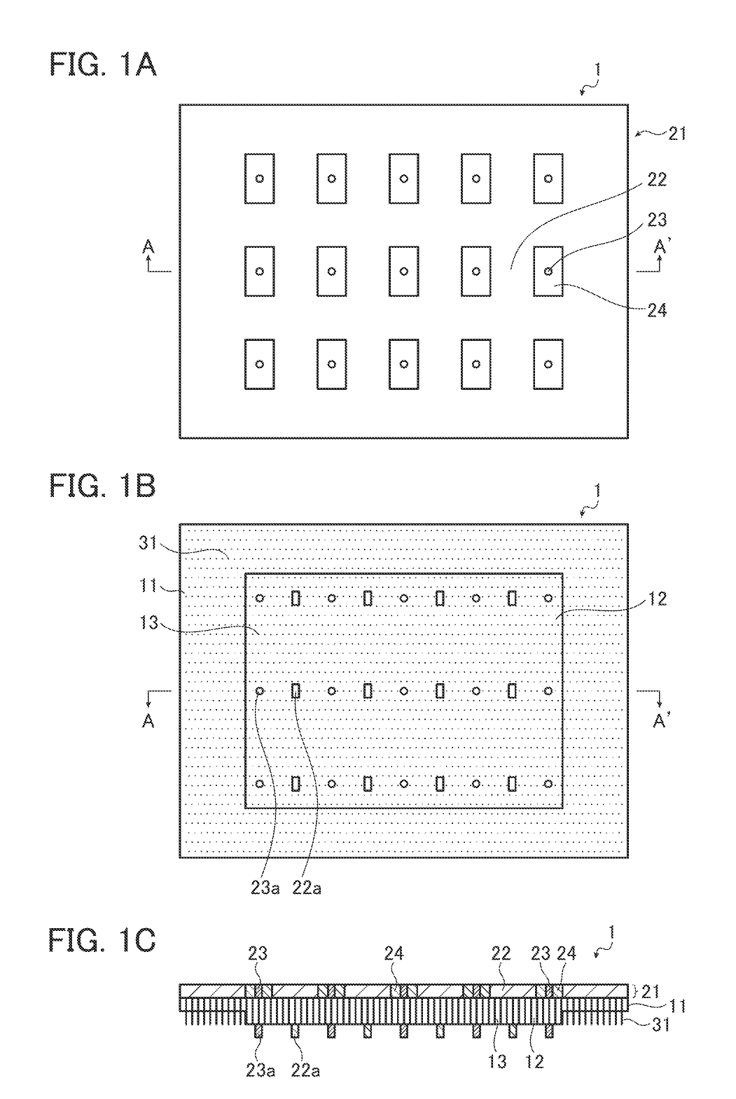

FIG. 1A is a plan view schematically illustrating a multi-layered board according to a first embodiment, FIG. 1B is a bottom view thereof, and FIG. 1C is a cross-sectional view taken along line A-A′ of FIG. 1A and line A-A′ of FIG. 1B.

The multi-layered board 1 according to the first embodiment is a multi-layered board having a layer formed of an anisotropically-conductive member 11 and a heat conducting layer 21 disposed on one surface of the anisotropically-conductive member 11. Heat dissipating portions 31 is are provided integrally in part of the anisotropically-conductive member 11.

### Anisotropically-Conductive Member

The anisotropically-conductive member 11 has an insulating base 12 and plural conduction passages 13 formed of a conductive material. The conduction passages 13 are provided to extend through the insulating base 12 in the thickness direction in a state where the conduction passages are insulated from each other. The conduction passages 13 are disposed in a state where one end of each conduction passage 13 is exposed at one surface of the insulating base 12 and the other end of each conduction passage 13 is exposed at the other surface of the insulating base 12. At least part of each conduction passage 13 present in the insulating base 12 is preferably approximately parallel to the thickness direction of the insulating base 12.

The insulating base and the conduction passages will be described below.

### Insulating Base

The insulating base constituting the anisotropically-conductive member is an anodized film of an aluminum substrate having through-holes. That is, the insulating base is an alumina film obtained by anodizing an aluminum substrate.

The thickness of the insulating base preferably ranges from 1 μm to 1000 μm, more preferably ranges from 5 μm to 500 μm, and still more preferably ranges from 10 μm to 300 μm.

The width between the conduction passages in the insulating base is preferably equal to or more than 5 nm and more preferably ranges from 10 nm to 200 nm. When the width between the conduction passages in the insulating base lies in this range, the insulating base can satisfactorily function as an insulating barrier wall.

For example, an insulating base described in paragraphs [0018] to [0025] of JP 2012-089481 A can be employed as the insulating base.

### Anodized Film of Aluminum Substrate

The insulating base is an anodized film of an aluminum substrate and can be manufactured by anodizing the aluminum substrate and subjecting micropores formed by the anodization to perforation. Here, the anodization and perforation steps will be described in a method of manufacturing an anisotropically-conductive member to be described later.

A micropore means a pore not penetrating a film formed at the time of anodizing the aluminum substrate and a hole obtained by subjecting the micropores to the perforation step to be described later is called through-hole.

### Aluminum Substrate

The aluminum substrate is not particularly limited, and any known aluminum substrate can be used. The aluminum substrate used in the present invention and the treatment steps performed on the aluminum substrate that can be employed are the same as those described in paragraphs [0039] to [0052] of JP 2009-164095 A.

### Conduction Passage

The conduction passages constituting the anisotropically-conductive member are formed of a conductive material.

Examples of the conductive material include materials of which the electrical resistivity is equal to or less than 10³ Ω·cm, and specific examples thereof include metals such as gold (Au), silver (Ag), copper (Cu), aluminum (Al), magnesium (Mg), and nickel (Ni) and so-called organic materials such as conductive polymers and carbon nanotubes. Among the materials, metals are preferable from the viewpoint of electrical conductivity. Among the metals, copper, gold, aluminum, and nickel are more preferable, and copper and gold are particularly preferable.

Each conduction passage has a cylindrical shape and the diameter thereof preferably ranges from 20 nm to 400 nm, more preferably ranges from 40 nm to 200 nm, and still more preferably ranges from 50 nm to 100 nm. When the diameter of the conduction passage lies within this range, a satisfactory response can be obtained when an electrical signal flows.

The conduction passages are present in a state where they are insulated from each other by the insulating base, and the density thereof is preferably equal to or more than 2,000,000 pieces/mm², more preferably equal to or more than 10,000,000 pieces/mm², still more preferably equal to or more than 50,000,000 pieces/mm², and most preferably equal to or more than 100,000,000 pieces/mm².

When the density of the conduction passages lie within this range, the multi-layered board according to the present invention can be used as a connector for inspection or an electrical connection member of an electronic component such as a semiconductor device even at the present in which a degree of integration is more advanced.

The distance between the centers of the neighboring conduction passages (hereinafter, also referred to as “pitch”) preferably ranges from 20 nm to 500 nm, more preferably from 40 nm to 200 nm, and still more preferably from 50 nm to 140 nm. When the pitch lies within this range, it is easy to keep the balance between the diameter of the conduction passages and the width between the conduction passages (the thickness of the insulating barrier wall).

The ratio of the length of the central line of each conduction passage to the thickness of the insulating base (length/thickness) preferably ranges from 1.0 to 1.2 and more preferably from 1.0 to 1.05. When the ratio of the length of the central line of each conduction passage to the thickness of the insulating base lies within this range, the conduction passages can be evaluated to have a straight tube structure and a one-to-one response can be secured when an electrical signal flows. Accordingly, the multi-layered board according to the present invention can be suitably used as a connector for inspection or an electrical connection member of an electronic component.

As described above, the conduction passages 13 are disposed in a state where one end of each conduction passage 13 is “exposed” at one surface of the insulating base 12 and the other end of each conduction passage 13 is “exposed” at the other surface of the insulating base 12. Here, the conduction passages 13 may be disposed in a state where one end of each conduction passage 13 “protrudes” from one surface of the insulating base 12 and the other end of each conduction passage 13 “protrudes” from the other surface of the insulating base 12.

That is, each conduction passage 13 may have a portion protruding from the principal surface of the insulating base 12 (hereinafter, also referred to as “protruding portion”) and a portion extending through the insulating base 12 (hereinafter, also referred to as “penetrating portion”).

The height of the protruding portion of each conduction passage 13 preferably ranges from 10 nm to 100 nm and more preferably from 10 nm to 50 nm. When the height of the protruding portion of each conduction passage 13 lies within this range, the contactability with electrode (pad) portions of an electronic component is improved, thereby obtaining a stable resistance value.

### Heat Dissipating Portion

The heat dissipating portions 31 protruding from the insulating base 12 are disposed in part of the anisotropically-conductive member 11. The heat dissipating portions 31 are formed of the conductive material constituting the conduction passages 13.

The shape of the heat dissipating portions 31 is not particularly limited and examples thereof include a rod shape and a plate shape. Among these shapes, the rod shape can be preferably used.

The surface area of the anisotropically-conductive member 11 is increased due to the heat dissipating portions 31, thereby improving heat dissipation performance. Since the heat dissipating portions 31 are formed in part of the anisotropically-conductive member 11 and are not disposed as other members, it is not necessary to secure a new space for the heat dissipating portions 31, thereby saving the space.

As described later, the heat dissipating portions 31 are preferably formed by performing a trimming treatment on the anisotropically-conductive member 11. In the trimming treatment, the conductive material constituting the conduction passages 13 is made to protrude, for example, by partially removing only the insulating base 12 on the surface of the anisotropically-conductive member 11 after manufacturing the anisotropically-conductive member 11. At this time, for example, an acid aqueous solution such as a phosphoric acid solution or an alkaline aqueous solution which do not dissolve the conductive material can be suitably used.

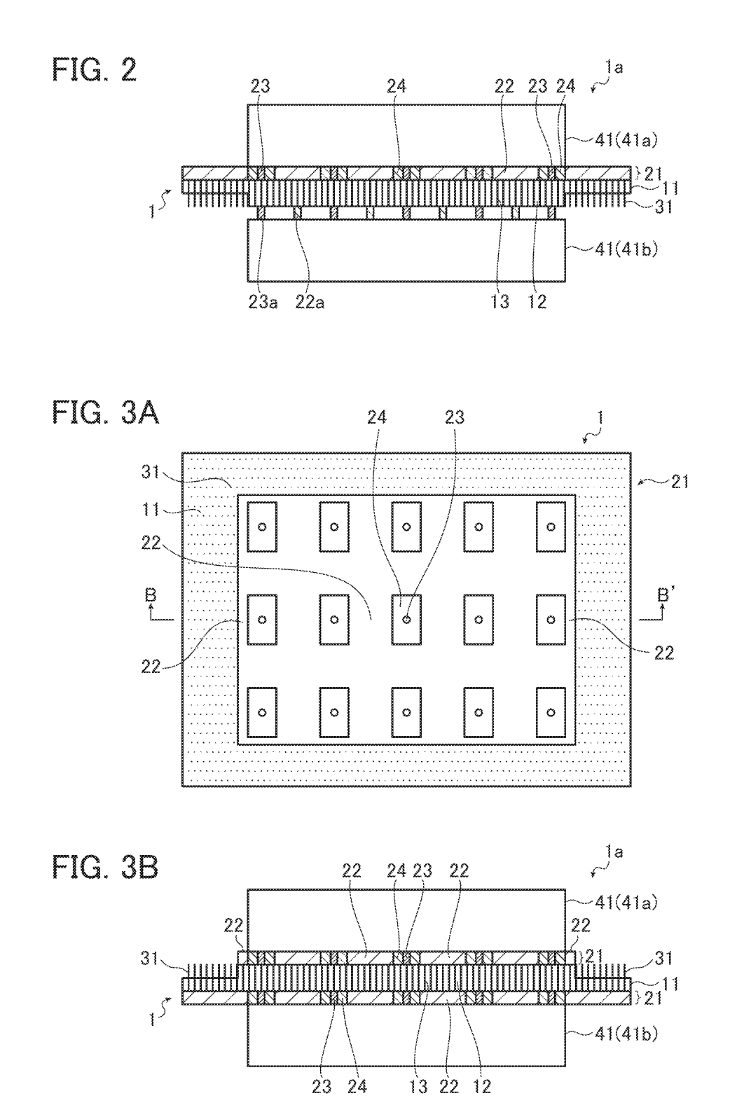

The heat dissipating portions 31 are not particularly limited in position, but are preferably formed outside the semiconductor device 41 (see FIG. 2) disposed on the multi-layered board 1.

From the viewpoint of heat dissipation performance of the semiconductor package, the area of the heat dissipating portions 31 is preferably equal to or more than 10% and more preferably equal to or more than 30% in a ratio to the mounted semiconductor device 41 (see FIG. 2) when the multi-layered board 1 is seen in a plan view or a bottom view. The upper limit of the area of the heat dissipating portions 31 is not particularly limited, but is preferably equal to or less than 100% from the viewpoint of compactness of the semiconductor package.

The height of the heat dissipating portions 31 (that is, the height protruding from the insulating base 12) is not particularly limited as long as it is larger than that of the conduction passages 13, but is preferably equal to or more than 10 nm, more preferably equal to or more than 1 μm, still more preferably equal to or more than 35 μm, particularly preferably equal to or more than 40 μm, and most preferably equal to or more than 50 μm, from the viewpoint of securing good heat dissipation performance. The height of the heat dissipating portions 31 is not particularly limited in the upper limit, but is preferably equal to or less than three quarters of the thickness of the insulating base 12 or equal to or less than 100 μm, from the viewpoint of the strength of the insulating base 12.

### Heat Conducting Layer

It is preferable that the heat conducting layer 21 formed on one surface of the anisotropically-conductive member 11 have heat conducting portions 22 formed of a heat conducting material and also have interconnecting portions 23 and insulating portions 24. As a result, it is preferable that the heat conducting layer 21 practically have the heat conducting portions 22, the interconnecting portions 23, and the insulating portions 24.

The thickness of the heat conducting layer 21 is not particularly limited, but preferably ranges from 0.5 μm to 1000 μm, more preferably ranges from 1 μm to 500 μm, and most preferably ranges from 5 μm to 250 μm, from the viewpoint of miniaturization of wiring, reliability of electrical conduction, thermal conductivity, and compactness of a semiconductor package.

### Heat Conducting Portion

The material of the heat conducting portions 22 is not particularly limited as long as it can conduct heat, and specific examples thereof include carbon nanotube, diamond, diamond-like carbon (DLC), silver (Ag), copper (Cu), gold (Au), aluminum (Al), silicon (Si), magnesium (Mg), brass, nickel (Ni), iron (Fe), platinum (Pt), and stainless steel. These materials may be used alone or in combination of two or more kinds thereof. Among these materials, Cu can be preferably used, because it is inexpensive and high in thermal conductivity.

The shape of the heat conducting portions 22 is not particularly limited, and examples thereof include a pattern shape, a dot shape, and a solid shape applied to a part other than the interconnecting portions 23 to be described later. Regarding the shape of the heat conducting portions 22, it is preferable that the heat conducting portions 22 be formed not only at inside position contacting the semiconductor device 41 to be described later (see FIG. 2) which is disposed on the multi-layered board 1, but also formed at position outside the semiconductor device 41 (see FIG. 2) and as shown in FIG. 1A, the heat conducting portions 22 are connected to each other as a whole so that heat can be conducted from the heat conducting portions 22 at the inside position toward the heat conducting portions 22 at the outside position.

From the viewpoint of thermal conductivity in the in-plane direction, a ratio of the area of the heat conducting portions 22 to that of the semiconductor device 41 (see FIG. 2) to be mounted when the multi-layered board 1 is seen in a plan view or a bottom view is preferably equal to or more than 10% and more preferably equal to or more than 30%. The upper limit of the area of the heat conducting portions 22 is not particularly limited, but is preferably equal to or less than an area with which the interconnecting portions 23 can be electrically insulated from the heat conducting portions 22.

### Interconnecting Portion

The interconnecting portions 23 are formed of a conductive material conducting electricity and serve as external connection electrodes. That is, the interconnecting portions connect wirings of the semiconductor device 41 (see FIG. 2) to be described later and the conduction passages 13.

The material of the interconnecting portions 23 is not particularly limited as long as it is a material conducting electricity, and specific examples thereof include gold (Au), silver (Ag), copper (Cu), aluminum (Al), magnesium (Mg), and nickel (Ni). These may be used alone or in combination of two or more kinds thereof.

Among these examples, Cu can be preferably used, because it has low electrical resistance. An Au layer or Ni/Au layer may be formed on the surface of the interconnecting portions 23 formed of Cu, from the viewpoint of improving facility of wire bonding.

The same material as the heat conducting portions 22 may be used as the material of the interconnecting portions 23. In this case, since the interconnecting portions 23 and the heat conducting portions 22 can be formed at the same time, it is possible to simplify the manufacturing process.

Examples of an embodiment in which the multi-layered board according to the present invention is connected to a semiconductor device and the like using the interconnecting portions include flip-chip interconnection by means of C4 (Controlled Collapse Chip Connection) bumps, solder balls, Cu pillars, or the like and interconnection using an anisotropically-conductive film (ACF) of a type in which conductive particles are arranged, but the embodiment of the present invention is not limited to these methods.

### Insulating Portion

The insulating portions 24 serve to insulate the interconnecting portions 23 from the heat conducting portions 22. The material of the insulating portions 24 is not particularly limited as long as it is a material having high insulating performance, and specific examples thereof include air; inorganic insulating materials such as glass and alumina; and organic insulating materials such as a resin. These may be used alone or in combination of two or more kinds thereof. Among these, the resin can be preferably used, because it is inexpensive and has high thermal conductivity.

A thermosetting resin can be preferably used as the resin. At least one selected from the group consisting of an epoxy resin, a modified epoxy resin, a silicone resin, a modified silicone resin, an acrylate resin, an urethane resin, and a polyimide resin can be preferably used as the thermosetting resin, and the epoxy resin, the modified epoxy resin, the silicone resin, and the modified silicone resin can be more preferably used.

In addition, a resin having excellent heat resistance, excellent weather resistance, and excellent light resistance can be preferably used as the resin.

In order to give a predetermined function to the resin, at least one selected from the group consisting of a filler, a diffusing agent, a pigment, a fluorescent material, a reflective material, an ultraviolet absorber, and an antioxidant may be mixed into the resin.

An adhesive composition may also be used as the resin, and examples thereof include adhesives for semiconductor commonly called an underfill material (liquid), an NCP (paste type), or an NCF (Non-Conductive Film) (film type). A dry film resist or the like may also be used.

Moreover, an anisotropically-conductive film (ACF) of a type in which conductive particles are arranged and which is also described for the interconnecting portions may be used as the insulating portions.

However, the embodiment of the insulating portions in the present invention is not limited to the above.

### Semiconductor Package

FIG. 2 is a cross-sectional view schematically illustrating a semiconductor package employing the multi-layered board according to the first embodiment.

A semiconductor package 1a has semiconductor devices 41 on both surfaces of the multi-layered board 1. Here, the semiconductor devices 41 are not particularly limited and examples thereof include a logic LSI (such as an ASIC, an FPGA, and an ASSP), a microprocessor (such as a CPU and a GPU), a memory (such as a DRAM, an HMC (Hybrid Memory Cube), an MRAM (Magnetic RAM), a PCM (Phase-Change Memory), an ReRAM (Resistive RAM), an FeRAM (Ferroelectric RAM), and a flash memory (NAND flash)), an LED (such as a micro flash of a mobile terminal, an in-vehicle light source, a projector light source, an LCD backlight, and general illuminations), a power device, an analog IC (such as a DC-DC converter and an insulating gate bipolar transistor (IGBT)), an MEMS (such as an acceleration sensor, a pressure sensor, a vibrator, and a gyro sensor), a wireless device (such as a GPS, an FM, an NFC, an RFEM, an MMIC, and a WLAN), a discrete device, a BSI, a CIS, a camera module, a CMOS, a passive device, a GAW filter, an RF filter, an RF IPD, an APE, and a BB.

In the semiconductor package 1a, more specifically, wirings (not shown) of one semiconductor device 41 (41a) are connected to the interconnecting portions 23 of the heat conducting layer 21 by thermocompression bonding, whereby the semiconductor device 41 (41a) comes in contact with the heat conducting portions 22 of the heat conducting layer 21.

Heat conducting portions 22a formed of the same material as the heat conducting portions 22 are similarly formed on the other surface of the multi-layered board 1, and interconnecting portions 23a formed of the same material as the interconnecting portions 23 are similarly formed thereon. Wirings (not shown) of the other semiconductor device 41 (41b) are connected to the interconnecting portions 23a by thermocompression bonding, whereby the semiconductor device 41 (41b) comes in contact with the heat conducting portions 22a.

That is, the semiconductor package 1a is a so-called three-dimensionally mounted type semiconductor package in which the semiconductor devices 41 are disposed on both surfaces of the multi-layered board 1 (the anisotropically-conductive member 11).

In the semiconductor package 1a, heat is generated from the semiconductor devices 41 on both surfaces thereof with driving of the semiconductor devices 41.

Meanwhile, in such a three-dimensionally mounted type semiconductor package like the semiconductor package 1a shown in FIG. 2, the anisotropically-conductive member and the semiconductor devices on both surfaces thereof form a multi-layered structure. Accordingly, heat generated from the semiconductor devices is likely to be confined in the inside of the multi-layered structure such as the gaps between the semiconductor devices and the anisotropically-conductive member.

At this time, if the anisotropically-conductive member interposed between two semiconductor devices has only the heat conducting portions 22 of the present invention (does not have the heat dissipating portions 31), heat may be dissipated via the heat conducting portions 22 but the anisotropically-conductive member is heated via the heat conducting portions 22, whereby heat is also confined in the inside thereof.

On the contrary, if the anisotropically-conductive member interposed between two semiconductor devices has only the heat dissipating portions 31 of the present invention (does not have the heat conducting portions 22), heat confined in the gaps between the semiconductor devices and the anisotropically-conductive member is not dissipated via the heat dissipating portions 31 but stays therein, whereby it cannot be said that the heat dissipation performance is high.

However, in the present invention, since the multi-layered board 1 has a combination of the heat conducting portions 22 and the heat dissipating portions 31, heat generated from the semiconductor devices 41 to the multi-layered board 1 is dissipated from the heat dissipating portions 31 via the anisotropically-conductive member 11 having the heat conducting portions 22, and thus heat is easily dissipated and is not likely to be confined therein.

As a result, in the present invention, high heat dissipation performance is obtained even in the three-dimensional mounting.

In the semiconductor package 1a, heat generated from the semiconductor devices 41 migrates to the heat conducting portions 22 (including the “heat conducting portions 22a”, the same applies hereinafter) in contact with the semiconductor devices 41. Since the heat conducting portions 22 are formed of a material conducting heat, heat is easily dissipated even in the heat conducting portions 22.

Particularly, in the semiconductor package 1a shown in FIG. 2, the width (the length in the horizontal direction in FIG. 2) of the anisotropically-conductive member 11 is larger than the width of the semiconductor devices 41 and the heat conducting portions 22 are also formed outside the semiconductor devices 41. The heat conducting portions 22 formed outside the semiconductor devices 41 are located at positions which are not likely to receive heat from the semiconductor devices 41 and thus are likely to be cooled. Since the heat conducting portions 22 have a shape in which they are connected to each other as a whole as shown in FIG. 1A, heat migrating from the semiconductor devices 41 to the heat conducting portions 22 migrates from the insides of the semiconductor devices 41 to the outsides thereof and is in a state where it is likely to be dissipated.

Moreover, in the semiconductor package 1a, since the heat dissipating portions 31 are disposed outside the semiconductor devices 41 similarly to the heat conducting portions 22, heat migrating to the outsides of the semiconductor devices 41 via the heat conducting portions 22 is particularly likely to be dissipated.

### Second Embodiment

FIG. 3A is a plan view schematically illustrating a semiconductor package according to a second embodiment in which a semiconductor device is omitted and FIG. 3B is a cross-sectional view taken along line B-B′ of FIG. 3A. In the second embodiment, the same constituents as in the first embodiment are referenced by the same reference signs and description thereof will not be repeated (the same applies hereinafter).

In the second embodiment, a heat conducting layer 21 is formed on both sides of an anisotropically-conductive member 11. Each of the heat conducting layers 21 on both surfaces is also formed outside semiconductor devices 41 and has a shape in which it is connective as a whole.

However, unlike the first embodiment, on one surface of a multi-layered board 1, the heat conducting layer 21 is not formed in the outermost part and the anisotropically-conductive member 11 is exposed. Heat dissipating portions 31 are formed in the exposed portion of the anisotropically-conductive member 11.

With this configuration, in both surfaces of the multi-layered board 1 according to the second embodiment, heat migrates to the outsides of the semiconductor devices 41 and is in a state where it is likely to be dissipated.

### Third Embodiment

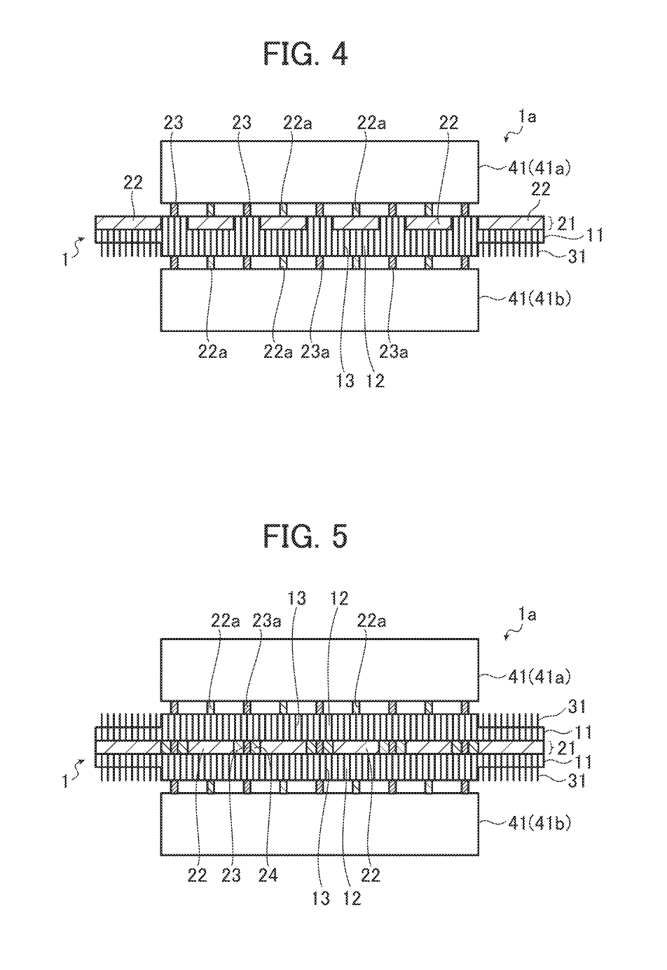

FIG. 4 is a diagram schematically illustrating a semiconductor package according to a third embodiment. In the third embodiment, heat conducting portions 22 are embedded in an anisotropically-conductive member 11.

In the heat conducting layer 21 of the first or second embodiment, miniaturization and thermal conductivity have a trade-off relationship. That is, when the heat conducting layer 21 disposed on the surface of the anisotropically-conductive member 11 increases in thickness, the thickness of the heat conducting portions 22 also increases. Accordingly, the heat conductivity is improved but the thickness of the interconnecting portions 23 also increases, which runs contrary to the miniaturization. On the other hand, when the heat conducting layer 21 decreases in thickness to miniaturize the interconnecting portions 23, the thickness of the heat conducting portions 22 also decreases and thus the thermal conductivity is relatively lowered.

However, as in the third embodiment, by embedding the heat conducting portions 22 in the anisotropically-conductive member 11, it is possible to keep the thickness of interconnecting portions 23 small without any change and to increase the thickness of only the heat conducting portions 22, thereby improving the thermal conductivity. That is, it is possible to break away from the trade-off relationship of the miniaturization and the thermal conductivity.

In the third embodiment, since the heat conducting portions 22 embedded in the anisotropically-conductive member 11 do not come in contact with semiconductor devices 41, heat conducting portions 22a formed of the same material as the heat conducting portions 22 can be disposed between the heat conducting portions 22 and the semiconductor devices 41 as shown in FIG. 4.

### Fourth Embodiment

FIG. 5 is a cross-sectional view schematically illustrating a semiconductor package according to a fourth embodiment. In the fourth embodiment, a heat conducting layer 21 is disposed between two anisotropically-conductive members 11. Heat generated from semiconductor devices 41 flows to the heat conducting layer 21 interposed between the two anisotropically-conductive members 11 and is dissipated from the outsides of the semiconductor devices 41.

### Fifth Embodiment

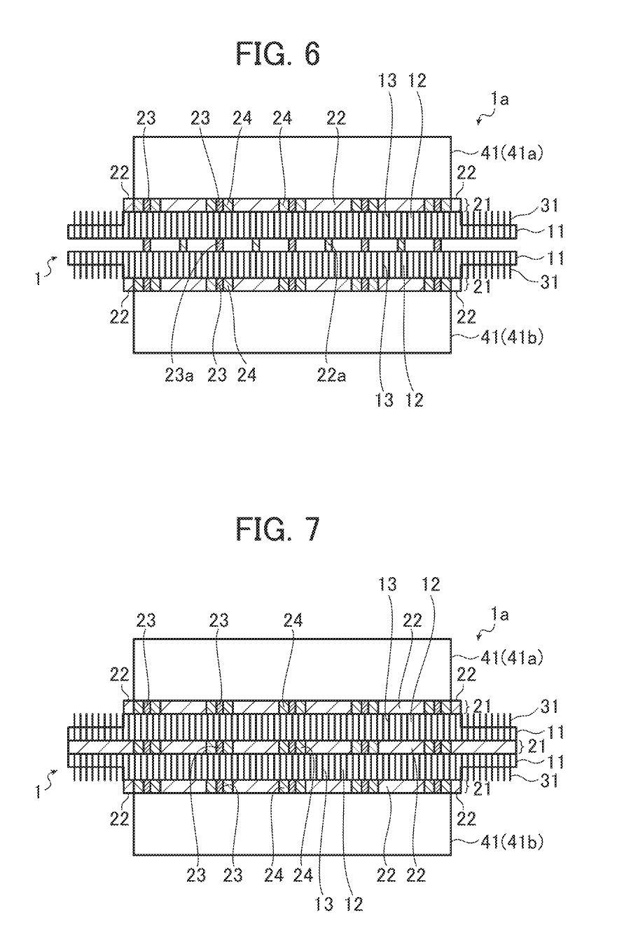

FIG. 6 is a cross-sectional view schematically illustrating a semiconductor package according to a fifth embodiment. In the fifth embodiment, a heat conducting layer 21 is disposed on the outer surface of each of two anisotropically-conductive members 11. Heat generated from semiconductor devices 41 flows to the closer heat conducting layer 21 and is dissipated from the outsides of the semiconductor devices 41.

### Sixth Embodiment

FIG. 7 is a cross-sectional view schematically illustrating a semiconductor package according to a sixth embodiment. In the sixth embodiment, three heat conducting layers 21 are disposed between two anisotropically-conductive members 11 and on the outer surfaces of the two anisotropically-conductive members 11. By employing this configuration, it is possible to further improve heat dissipation performance.

The present invention is not limited to the above-mentioned embodiments, and examples of the mounting type thereof include SoC, SiP, PoP, PiP, CSP, and TSV.

More specifically, the multi-layered board according to the present invention can also be used, for example, as a grounding part or a heat conducting part in addition to connection of a data signal or a power supply in a simple semiconductor device.

The multi-layered board according to the present invention can also be used as a grounding part or a heat conducting part in addition to connection of a data signal or a power supply between two or more semiconductor devices. In this embodiment, the multi-layered board according to the present invention can be used, for example, as an interposer in the following examples.
Logic device of three-dimensional SoC (such as a homogeneous board (in which plural FPGA layers are stacked on an interposer) and a heterogeneous board (in which a digital device, an analog device, an RF device, an MEMS, and a memory are stacked on an interposer))
Three-dimensional SiP (wide I/O) in which logic and memory are combined (such as a board in which a CPU and a DRAM are stacked above or above and below an interposer, a board in which a GPU and a DRAM are stacked above or above and below an interposer, a board in which an ASIC/FPGA and a wide I/O memory are stacked above or above and below an interposer, and a board in which an APE and a wide I/O memory are stacked above or above and below an interposer)
2.5-dimensional heterogeneous board in which an SoC and a DRAM are combined

The multi-layered board according to the present invention can also be used for connection between a semiconductor package and a printed circuit board (not shown).

The multi-layered board according to the present invention can also be used for connection (PoP) between two or more semiconductor packages. As an embodiment of this case, the multi-layered board according to the present invention is connected to two semiconductor packages disposed on both surfaces thereof via a predetermined interconnecting part.

In addition, the application of the multi-layered board according to the present invention is not limited to the above-mentioned applications. For example, an interposer can be manufactured with a simplified interconnecting process by bonding the multi-layered board and a silicon interposer or a glass interposer together.

Moreover, the multi-layered board according to the present invention can also be used for connection between a printed circuit board or a flexible board and a rigid board, connection between flexible boards, connection between rigid boards, and the like.

The multi-layered board according to the present invention can also be used as a probe of inspection equipment or a simple heat sink.

A final product employing the multi-layered board according to the present invention and the semiconductor package according to the present invention described above is not particularly limited, and examples thereof include a smart TV, a mobile communication terminal, a mobile phone, a smartphone, a tablet terminal, a desktop PC, a notebook PC, network equipment (such as a router and a switching instrument), wired infrastructure equipment, a digital camera, a game console, a controller, a data center, a server, an HPC, a graphic card, a network server, a storage, a chip set, an in-vehicle apparatus (such as an electronic control unit and a driving support system), a car navigation system, a PND, an illumination (such as a general illumination, an in-vehicle illumination, an LED illumination, and an OLED illumination), a television, a display, a display panel (such as a liquid crystal panel, an organic EL panel, and an electronic paper), a music player terminal, industrial equipment, an industrial robot, an inspecting apparatus, a medical device, white goods, space and aircraft equipment, a wearable device, and the like.

Next, a method of manufacturing the anisotropically-conductive member will be described below and then methods of manufacturing the multi-layered board according to the present invention and the semiconductor package according to the present invention will be described.

### Method of Manufacturing Anisotropically-Conductive Member

The method of manufacturing the anisotropically-conductive member is not particularly limited and preferably includes the following steps.

Anodization step: a step of anodizing the aluminum substrate

Perforation step: a step of subjecting, after the anodization step, micropores formed by the anodization to perforation to obtain the insulating base

Filling step: a filling step of filling, after the perforation step, the inside of the through-holes in the obtained insulating base with a conductive material to obtain the anisotropically-conductive member

The sequence of the steps will be described below in detail.

### Method of Manufacturing Anisotropically-Conductive Members According to First, Second, and Fourth to Sixth Embodiments

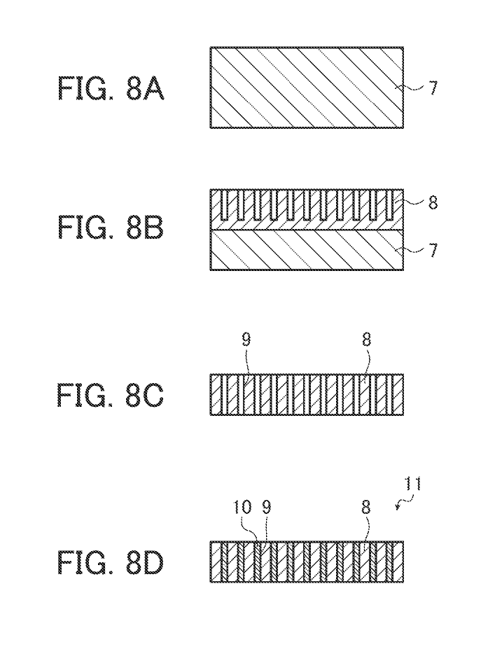

FIGS. 8A to 8D are cross-sectional views schematically illustrating a method of manufacturing the anisotropically-conductive members according to the first, second, and fourth to sixth embodiments.

As shown in FIGS. 8A to 8D, the anisotropically-conductive member 11 can be manufactured through a manufacturing method having an anodization step (see FIGS. 8A and 8B) of forming an anodized film 8 by anodizing the surface of an aluminum substrate 7, a perforation step (see FIG. 8C) of removing the aluminum substrate 7 and perforating the anodized film 8, and a filling step (see FIG. 8D) of filling the insides of through-holes 9 of the anodized film 8 with a metal 10, in this order.

### Method (Method 1) of Manufacturing Anisotropically-Conductive Member According to Third Embodiment

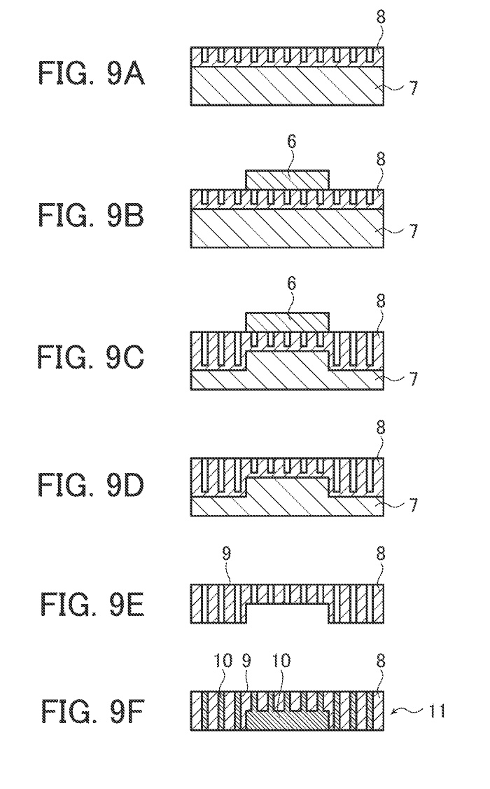

FIGS. 9A to 9F are cross-sectional views schematically illustrating a method (Method 1) of manufacturing the anisotropically-conductive member according to the third embodiment.

As shown in FIGS. 9A to 9F, the anisotropically-conductive member 11 can be manufactured through a manufacturing method having an anodization step (see FIG. 9A) of forming an anodized film 8 by anodizing the surface of an aluminum substrate 7, a mask layer forming step (see FIG. 9B) of forming a mask layer 6 having a predetermined opening pattern on the surface of the anodized film 8, an anodization step (see FIG. 9C) of forming an anodized film 8 by anodizing the opening portions of the mask layer 6, a mask layer removing step (see FIG. 9D) of removing the mask layer 6, a perforation step (see FIG. 9E) of removing the aluminum substrate 7 and perforating the anodized film 8, and a filling step (see FIG. 9F) of filling the insides of through-holes 9 of the anodized film 8 with a metal 10, in this order.

### Method (Method 2) of Manufacturing Anisotropically-Conductive Member According to Third Embodiment

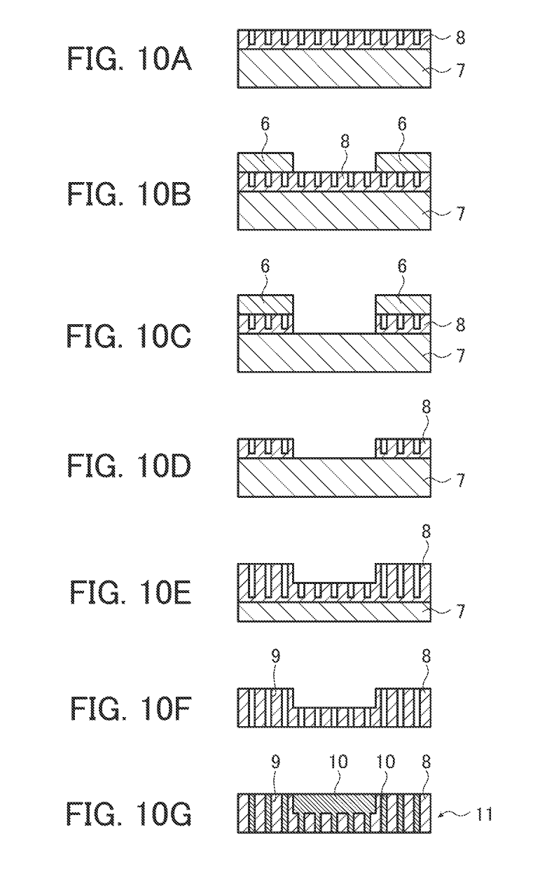

FIGS. 10A to 10G are cross-sectional views schematically illustrating a method (Method 2) of manufacturing the anisotropically-conductive member according to the third embodiment.

As shown in FIGS. 10A to 10G, the anisotropically-conductive member 11 can be manufactured through a manufacturing method having an anodization step (see FIG. 10A) of forming an anodized film 8 by anodizing the surface of an aluminum substrate 7, a mask layer forming step (see FIG. 10B) of forming a mask layer 6 having a predetermined opening pattern on the surface of the anodized film 8, a film removing step (see FIG. 10C) of removing a part of the anodized film 8 from the opening portions of the mask layer 6, a mask layer removing step (see FIG. 10D) of removing the mask layer 6, an anodization step (see FIG. 10E) of forming an anodized film 8 by performing a second anodization process on the aluminum substrate 7 from which the mask layer 6 has been removed, a perforation step (see FIG. 10F) of removing the aluminum substrate 7 and perforating the anodized film 8, and a filling step (see FIG. 10G) of filling the insides of through-holes 9 of the anodized film 8 with a metal 10, in this order.

### Method (Method 3) of Manufacturing Anisotropically-Conductive Member According to Third Embodiment

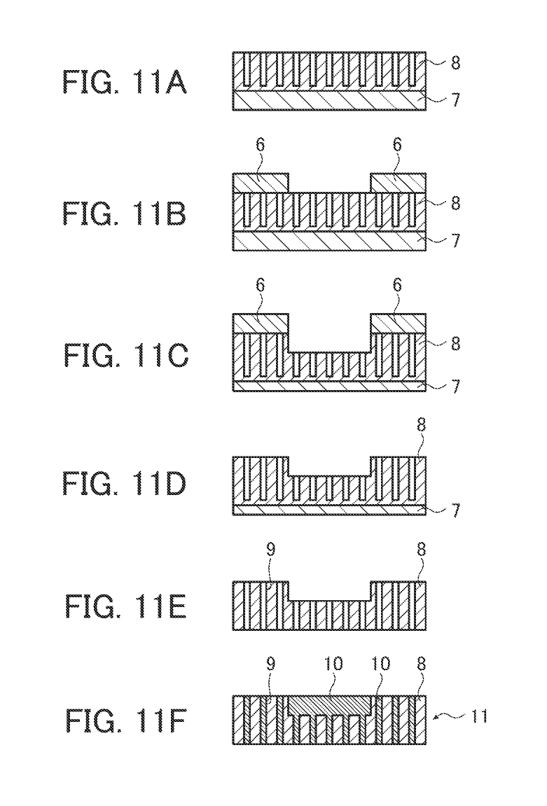

FIGS. 11A to 11F are cross-sectional views schematically illustrating a method (Method 3) of manufacturing the anisotropically-conductive member according to the third embodiment.

As shown in FIGS. 11A to 11F, the anisotropically-conductive member 11 can be manufactured through a manufacturing method having an anodization step (see FIG. 11A) of forming an anodized film 8 by anodizing the surface of an aluminum substrate 7, a mask layer forming step (see FIG. 11B) of forming a mask layer 6 having a predetermined opening pattern on the surface of the anodized film 8, a film removing step (see FIG. 11C) of removing a part of the anodized film 8 from the opening portions of the mask layer 6, a mask layer removing step (see FIG. 11D) of removing the mask layer 6, a perforation step (see FIG. 11E) of removing the aluminum substrate 7 and perforating the anodized film 8, and a filling step (see FIG. 11F) of filling the insides of through-holes 9 of the anodized film 8 with a metal 10, in this order.

### Method (Method 4) of Manufacturing Anisotropically-Conductive Member According to Third Embodiment

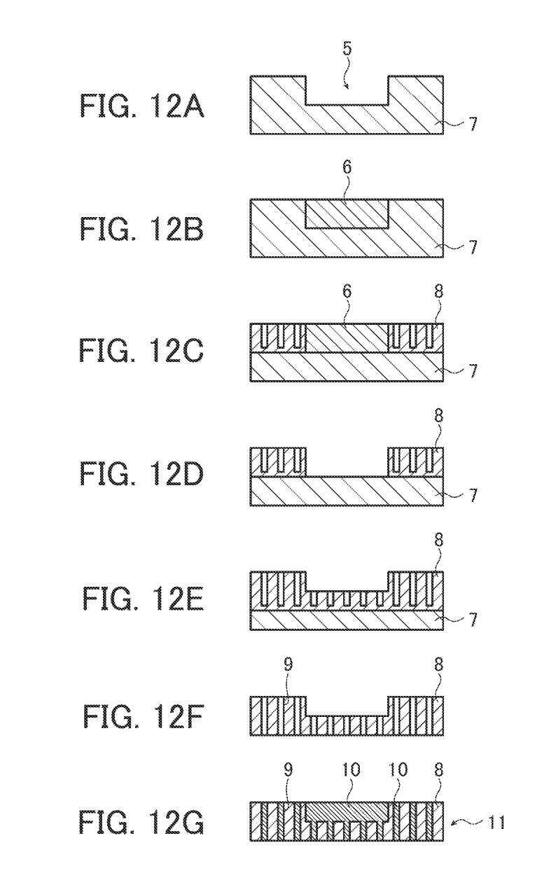

FIGS. 12A to 12G are cross-sectional views schematically illustrating a method (Method 4) of manufacturing the anisotropically-conductive member according to the third embodiment.

As shown in FIGS. 12A to 12G, the anisotropically-conductive member 11 can be manufactured through a manufacturing method having a depression forming step (see FIG. 12A) of forming a depression 5 in a part of the surface of an aluminum substrate 7, a mask layer forming step (see FIG. 12B) of forming a mask layer 6 in the depression 5, an anodization step (see FIG. 12C) of forming an anodized film 8 by anodizing the aluminum substrate 7 having the mask layer 6 formed thereon, a mask layer removing step (see FIG. 12D) of removing the mask layer 6, an anodization step (see FIG. 12E) of forming an anodized film 8 by performing a second anodization process on the aluminum substrate 7 from which the mask layer 6 has been removed, a perforation step (see FIG. 12F) of removing the aluminum substrate 7 and perforating the anodized film 8, and a filling step (see FIG. 12G) of filling the insides of through-holes 9 of the anodized film 8 with a metal 10, in this order.

### Method (Method 5) of Manufacturing Anisotropically-Conductive Member According to Third Embodiment

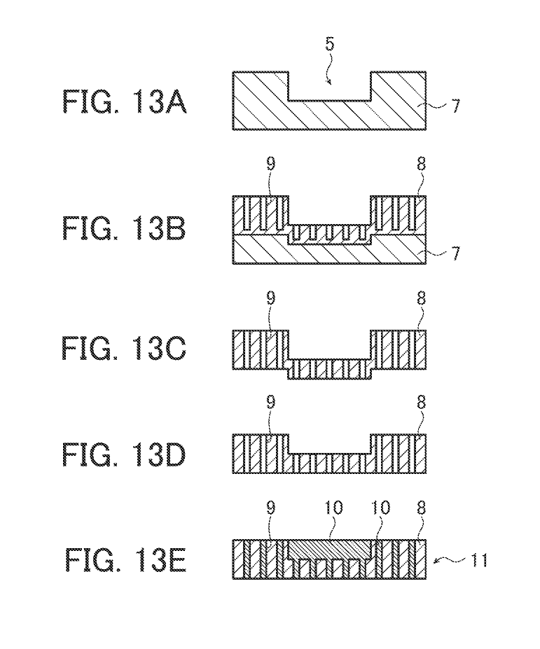

FIGS. 13A to 13E are cross-sectional views schematically illustrating a method (Method 5) of manufacturing the anisotropically-conductive member according to the third embodiment.

As shown in FIGS. 13A to 13E, the anisotropically-conductive member 11 can be manufactured through a manufacturing method having a depression forming step (see FIG. 13A) of forming a depression 5 in a part of the surface of an aluminum substrate 7, an anodization step (see FIG. 13B) of forming an anodized film 8 by anodizing the aluminum substrate 7, a perforation step (see FIG. 13C) of removing the aluminum substrate 7 and perforating the anodized film 8, a surface smoothing step (see FIG. 13D) of smoothing the anodized film 8, and a filling step (see FIG. 13E) of filling the insides of through-holes 9 of the anodized film 8 with a metal 10, in this order.

### Method (Method 6) of Manufacturing Anisotropically-Conductive Member According to Third Embodiment

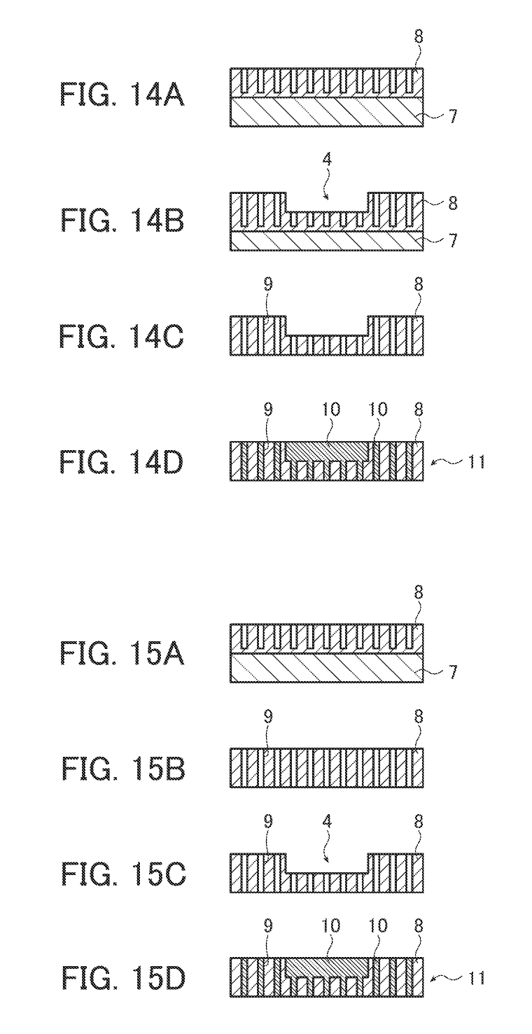

FIGS. 14A to 14D are cross-sectional views schematically illustrating a method (Method 6) of manufacturing the anisotropically-conductive member according to the third embodiment.

As shown in FIGS. 14A to 14D, the anisotropically-conductive member 11 can be manufactured through a manufacturing method having an anodization step (see FIG. 14A) of forming an anodized film 8 by anodizing the surface of an aluminum substrate 7, a recess forming step (see FIG. 14B) of forming a recess 4 in a part in the depth direction of the anodized film 8, a perforation step (see FIG. 14C) of removing the aluminum substrate 7 and perforating the anodized film 8, and a filling step (see FIG. 14D) of filling the insides of through-holes 9 of the anodized film 8 with a metal 10, in this order.

### Method (Method 7) of Manufacturing Anisotropically-Conductive Member According to Third Embodiment

FIGS. 15A to 15D are cross-sectional views schematically illustrating a method (Method 7) of manufacturing the anisotropically-conductive member according to the third embodiment.

As shown in FIGS. 15A to 15D, the anisotropically-conductive member 11 can be manufactured through a manufacturing method having an anodization step (see FIG. 15A) of forming an anodized film 8 by anodizing the surface of an aluminum substrate 7, a perforation step (see FIG. 15B) of removing the aluminum substrate 7 and perforating the anodized film 8, a recess forming step (see FIG. 15C) of forming a recess 4 in a part in the depth direction of the anodized film 8, and a filling step (see FIG. 15D) of filling the insides of through-holes 9 of the anodized film 8 with a metal 10, in this order.

### Method (Method 8) of Manufacturing Anisotropically-Conductive Member According to Third Embodiment

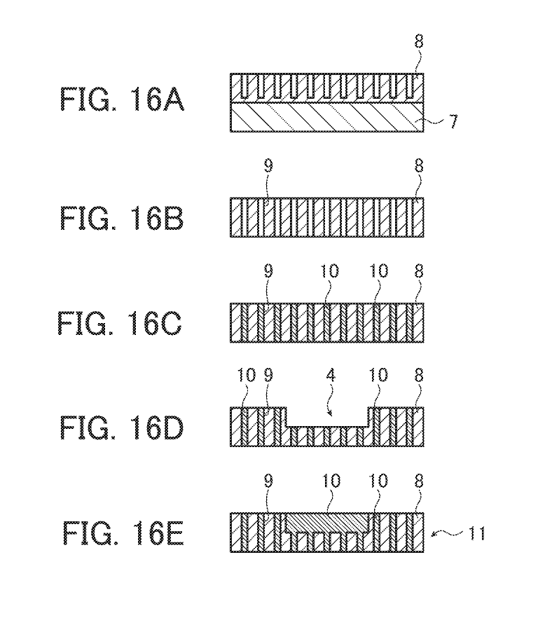

FIGS. 16A to 16E are cross-sectional views schematically illustrating a method (Method 8) of manufacturing the anisotropically-conductive member according to the third embodiment.

As shown in FIGS. 16A to 16E, the anisotropically-conductive member 11 can be manufactured through a manufacturing method having an anodization step (see FIG. 16A) of forming an anodized film 8 by anodizing the surface of an aluminum substrate 7, a perforation step (see FIG. 16B) of removing the aluminum substrate 7 and perforating the anodized film 8, a filling step (see FIG. 16C) of filling the insides of through-holes 9 of the anodized film 8 with a metal 10, a recess forming step (see FIG. 16D) of forming a recess 4 in a part in the depth direction of the anodized film 8, and a filling step (see FIG. 16E) of filling the recess 4 with a metal 10, in this order.

Next, the steps which are included in the methods of manufacturing the anisotropically-conductive members will be described below in detail.

### Anodization Step

A known method can be used in the anodization carried out in the anodization step, but since the insulating base is preferably an anodized film of an aluminum substrate in which through-holes are arranged so that a degree of ordering defined by Expression (i) described in paragraphs [0019] and [0020] of JP 2012-089481 A is equal to or more than 50%, a self-ordering method to be described later can be preferably used.

In paragraphs [0019] and [0020] of JP 2012-089481 A, Expression (i) is defined as follows.

Degree of Ordering(%)=B/A×100 (i)

In Expression (i), A represents the total number of through-holes in a measurement region, and B represents the number of specific through-holes in the measurement region for which, when a circle is drawn so as to be centered on the center of gravity of a specific through-hole and so as to be of the smallest radius that is internally tangent to the edge of another through-hole, the circle includes the centers of gravity of six through-holes other than the specific through-hole.

The self-ordering method is a method which enhances the orderliness by using the regularly arranging nature of micropores in an anodized film obtained by anodization and eliminating factors that may disturb an orderly arrangement. Specifically, an anodized film is formed on high-purity aluminum at a voltage appropriate for the type of electrolytic solution and at a low speed over an extended period of time (e.g., from several hours to well over ten hours).

In this method, since the diameter of the micropores (pore diameter) depends on the voltage, it is possible to obtain a desired pore diameter to a certain extent by controlling the voltage.

Preferable examples of the method of forming micropores using the self-ordering method include a method (Self-ordering Method I) of performing an anodization treatment (A), a film removing treatment (B), and a re-anodization treatment (C) in this order and a method (Self-ordering Method II) of performing an anodization treatment (D) and an anodized film dissolving treatment (E) in this order at least once.

Details of the treatments in Self-ordering Method I and Self-ordering Method II which are preferable embodiments are described in paragraphs [0074] to [0113] of JP 2012-089481 A.

### Mask Layer Forming Step

The mask layer forming step is a step of forming a mask layer having a predetermined opening pattern (opening portions) on the surface of the anodized film formed through the anodization step in the embodiments shown in FIGS. 9B, 10B and 11B, and is a step of forming a mask layer in a depressed portion formed in the aluminum substrate in the embodiment shown in FIG. 12B.

The mask layer can be formed using a method which involves forming an image recording layer on the surface of the anodized film, applying energy to the image recording layer by light exposure or heating to develop the image recording layer into a predetermined opening pattern in the embodiments shown in FIGS. 9 B, 10B and 11B. The mask layer can be formed using a method which involves forming an image recording layer in the depressed portion formed in the aluminum substrate and applying energy to the entire surface of the image recording layer by light exposure or heating to cure the image recording layer in the embodiment shown in FIG. 12B.

Here, the material for forming the image recording layer is not particularly limited, and a conventionally known material for forming a photosensitive layer (photoresist layer) or a thermosensitive layer can be used. The material for forming the image recording layer may include an additive such as an infrared absorber if necessary.

### Mask Layer Removing Step

The mask layer removing step is a step of removing the mask layer.

Here, the method of removing the mask layer is not particularly limited, and for example, a method which involves dissolving and removing the mask layer by using a solution which dissolves the mask layer but does not dissolve the aluminum substrate and the anodized film can be used. Examples of such a solution include known developing solutions, when a photosensitive layer or a thermosensitive layer is used as the mask layer.

### Film Removing Step

The film removing step is a step of removing the anodized film present under the openings of the mask layer, as shown in FIGS. 10C and 11C.

Here, the method of removing the anodized film is not particularly limited, and for example, a method of dissolving the anodized film using an alkaline aqueous etching solution or an acid aqueous solution can be used.

### Depression Forming Step

The depression forming step is a step of forming a depression in a part of the surface of the aluminum substrate, as shown in FIGS. 12A and 13A.

Here, the method of forming the depression is not particularly limited, and for example, a method of forming the depression by pressing a mold against the aluminum substrate can be used.

### Recess Forming Step

The recess forming step is a step of forming a recess in a part in the depth direction of the anodized film, as shown in FIGS. 14B, 15C and 16D.

Here, the method of forming the recess is not particularly limited, and for example, a method of chemically dissolving the anodized film through the use of an etching treatment or the like or a method of mechanically removing the anodized film using a dicer or the like can be used.

### Water Washing Treatment

A water washing treatment is preferably performed after the above-mentioned steps end. Purified water, well water, tap water, and the like can be used for the water washing. A nip apparatus may be used to prevent a treatment liquid from being introduced into next steps.

### Perforation Step

The perforation step is a step of subjecting, after the anodization step, micropores formed through the anodization step to perforation to obtain an insulating base having through-holes.

Specific examples of the perforation step include a method which involves dissolving the aluminum substrate after the anodization step to remove the bottom portion of the anodized film and a method which involves cutting the aluminum substrate and the anodized film in the vicinity of the aluminum substrate after the anodization step.

The former method which is a more suitable embodiment will be described below.

### Dissolving of Aluminum Substrate

The dissolving of the aluminum substrate after the anodization step is performed using a treatment liquid which is not likely to dissolve the anodized film (alumina) but is likely to dissolve aluminum.

That is, a treatment liquid is used which has conditions of an aluminum dissolving speed of 1 μm/min or more, preferably 3 μm/min or more, and more preferably 5 μm/min or more and an anodized film dissolving speed of 0.1 nm/min or less, preferably 0.05 nm/min or less, and more preferably 0.01 nm/min or less.

Specifically, an immersion treatment is carried out using a treatment liquid which contains at least one kind of metal compound having an ionization tendency lower than that of aluminum and which has a pH of 4 to 8, preferably 3 to 9, and more preferably 2 to 10.

Preferable examples of such a treatment liquid include acid or alkaline aqueous solutions used as a base into which a compound of manganese, zinc, chromium, iron, cadmium, cobalt, nickel, tin, lead, antimony, bismuth, copper, mercury, silver, palladium, platinum or gold (for example, a chloroplatinate), a fluoride thereof, or a chloride thereof is mixed.

Among these, an acid aqueous solution is preferably used as the base, and a chloride is preferably mixed into the acid aqueous solution.

Particularly, a treatment liquid in which mercury chloride is mixed into a hydrochloric acid aqueous solution (hydrochloric acid/mercury chloride) and a treatment liquid in which copper chloride is mixed into a hydrochloric acid aqueous solution (hydrochloric acid/copper chloride) can be preferably used from the viewpoint of treatment latitude.

The composition of such a treatment liquid is not particularly limited, and for example, a bromine/methanol mixture, a bromine/ethanol mixture, and an aqua regia, and the like can be used.

In addition, the acid or alkali concentration of the treatment liquid preferably ranges from 0.01 mol/L to 10 mol/L and more preferably from 0.05 mol/L to 5 mol/L.

Moreover, the treating temperature at which such a treatment liquid is used preferably ranges from −10° C. to 80° C. and more preferably from 0° C. to 60° C.

The dissolving of the aluminum substrate is carried out by bringing the aluminum substrate subjected to the anodization step into contact with the treatment liquid. The contact method is not particularly limited and examples thereof include a immersion method and a spraying method. Among these, the immersion method can be preferably used. The contact time is preferably ranges from 10 seconds to 5 hours and more preferably from 1 minute to 3 hours.

### Removal of Bottom Portion of Anodized Film

The removal of the bottom portion of the anodized film after dissolving the aluminum substrate is carried out by immersing the anodized film in an acid aqueous solution or an alkaline aqueous solution. By removing the bottom portion of the anodized film, through-holes are formed from the micropores.

The bottom of the anodized film is preferably removed by the method which involves previously immersing the anodized film in a pH buffer solution to fill the holes formed from the micropores with the pH buffer solution from the hole opening side, and bringing the surface opposite from the openings (i.e., the bottom of the anodized film) into contact with an aqueous acid solution or aqueous alkali solution.

When the acid aqueous solution is used, an aqueous solution of an inorganic acid such as sulfuric acid, phosphoric acid, nitric acid or hydrochloric acid, or a mixture thereof is preferably used. The concentration of the acid aqueous solution preferably ranges from 1 wt % to 10 wt %. The temperature of the acid aqueous solution preferably ranges from 25° C. to 40° C.

On the other hand, when the alkaline aqueous solution is used, an aqueous solution of at least one alkali selected from the group consisting of sodium hydroxide, potassium hydroxide, and lithium hydroxide is preferably used. The concentration of the alkaline aqueous solution preferably ranges from 0.1 wt % to 5 wt %. The temperature of the alkaline aqueous solution preferably ranges from 20° C. to 35° C.

Specific examples of solutions that may be preferably used include a 40° C. aqueous solution containing 50 g/L of phosphoric acid, a 30° C. aqueous solution containing 0.5 g/L of sodium hydroxide, and a 30° C. aqueous solution containing 0.5 g/L of potassium hydroxide.

The time of immersion in the acid aqueous solution or the alkaline aqueous solution preferably ranges from 8 minutes to 120 minutes, more preferably from 10 minutes to 90 minutes, and still more preferably from 15 minutes to 60 minutes.

When the anodized film is immersed in the pH buffer solution in advance, a buffer solution suitable to the above-mentioned acids/alkalis is used.

On the other hand, an example of the latter method that may be advantageously used to cut the aluminum substrate and the anodized film in the vicinity of the aluminum substrate includes one which involves physically removing the aluminum substrate and the bottom of the anodized film by cutting with a laser beam or other various polishing treatments.

### Filling Step

The filling step is a step in which a conductive material is filled into through-holes in the resulting insulating base after the perforation step to obtain the anisotropically-conductive member.

Here, the conductive material filled therein constitutes the conduction passages of the anisotropically-conductive member and the types thereof are as described above.

An electrolytic plating method or an electroless plating method can be used as the method of filling the through-holes with a metal as the conductive material.

Electrolytic plating is preferably preceded by electrode film-forming treatment to form an electrode film having no void on one surface of the insulating base.

The method of forming the electrode film is not particularly limited and preferred examples thereof include electroless plating of a metal and direct application of a conductive material such as a metal. Of these, electroless plating is more preferred in terms of the uniformity of the electrode film and the ease of operation. When electroless plating is used for electrode film-forming treatment, it is preferred to form plating nuclei on one surface of the anodized film. More specifically, a method is preferably used in which a metal or metal compound of the same type as a specific metal to be provided by electroless plating or a metal or metal compound having a higher ionization tendency than a specific metal to be provided by electroless plating is provided on one surface of the insulating base. Exemplary methods of providing such metal or metal compound include vapor deposition, sputtering and direct application, but the invention is not particularly limited to these methods.

After the plating nuclei have been provided as described above, the electrode film is formed by electroless plating. Immersion is a preferable treatment method from the viewpoint that the thickness of the electrode layer can be controlled by the temperature and the time.

Any conventionally known type of electroless plating solution may be used.

Noble metal-containing plating solutions such as a gold plating solution, a copper plating solution and a silver plating solution are preferable in terms of increasing the electrical continuity of the electrode film to be formed, and a gold plating solution is more preferable in terms of the long-term stability of the electrode, that is, the prevention of the deterioration due to oxidation.

In the manufacturing method according to the present invention, when a metal is filled using the electrolytic plating method, a downtime is preferably provided to the time of pulse electrolysis or controlled-potential electrolysis. It is necessary that the downtime is equal to or more than 10 seconds, and preferably, the down time ranges from 30 seconds to 60 seconds.

In addition, it is preferable that ultrasonic waves be applied to the electrolytic solution to promote stirring thereof.

Moreover, the electrolysis voltage is generally equal to or lower than 20V and preferably equal to or lower than 10 V, but it is preferable that the deposition potential of a target metal in the used electrolytic solution be measured in advance and the controlled-potential electrolysis be carried out within the measured potential+1 V. When the controlled-potential electrolysis is carried out, cyclic voltammetry can be preferably used together. In this case, a potentiostat made by Solartron Analytical Inc., BAS Inc., Hokuto Denko Corporation, IVIUM Technologies B.V., or the like can be used.

Conventionally known plating solutions can be used for the plating solution used for filling with a metal.

Specifically, a copper sulfate aqueous solution is generally used to deposit copper, and the concentration of copper sulfate preferably ranges from 1 g/L to 300 g/L and more preferably from 100 g/L to 200 g/L. The deposition can be promoted by adding hydrochloric acid to the electrolytic solution. In this case, the concentration of hydrochloric acid preferably ranges from 10 g/L to 20 g/L.

When gold is to be deposited, the plating is preferably carried out using a sulfuric acid solution of a tetrachloroaurate through AC electrolysis.

Since a long time is required for completely filling a hole having a high aspect ratio with a metal in the electroless plating method, it is preferable that the holes be filled with a metal using the electrolytic plating method.

In the third embodiment, as shown in FIGS. 9F, 10G, 11F, 12G, 13E, 14D, 15D and 16E, the heat conducting portions embedded in the heat conducting layer can be formed together in the filling step.

### Sealing Step

After performing the filling step, if necessary, a sealing step of sealing the insulating base filled with the metal so as to secure the sealing rate of 99% or more may be performed. When the sealing rate is within this range, it is possible to suppress failure of interconnections.

The sealing treatment to be performed is not particularly limited, and known methods such as boiling water treatment, hot water treatment, steam treatment, silicate soda treatment, nitrite treatment, and ammonium acetate treatment can be used. For example, apparatuses and methods described in JP 56-12518 B, JP 4-4194 A, JP 5-202496 A, JP 5-179482 A, and the like may be used to perform the sealing treatment.

### Surface Smoothing Step

A surface smoothing step of smoothing the top surface and the bottom surface through a polishing treatment (for example, a chemical-mechanical polishing treatment) is preferably performed after the filling step.

Particularly, it is preferable that the top surface and the bottom surface after the filling with a metal be smoothed and the extra metal adhering to the surfaces be removed, by performing a CMP (Chemical Mechanical Polishing) treatment as the chemical-mechanical polishing treatment.

CMP slurries such as PNANERLITE-7000 made by Fujimi Incorporated, GPX HSC800 made by Hitachi Chemical Co., Ltd., and CL-1000 made by Asahi Glass (Seimi Chemical) Co., Ltd. can be used in the CMP treatment.

Since it is not desired to polish the anodized film, it is not preferable that the slurry for an interlayer dielectric film or a barrier metal be used.

### Heat Dissipating Portion Forming Step

In the present invention, a heat dissipating portion forming step of forming the heat dissipating portions in any part of the anisotropically-conductive member is provided after the filling step or the surface smoothing step.

The heat dissipating portion forming step is a step of partially removing only the anodized film as the insulating base from the surface of the anisotropically-conductive member having the conduction passages formed therein, for example, using a trimming treatment to cause the conductive material of the conduction passages to protrude.

Here, the trimming treatment is performed under the condition under which the conductive material (for example, a metal) of the conduction passages is not dissolved. For example, the trimming treatment is performed by bringing the anisotropically-conductive member into contact with an acid aqueous solution or an alkaline aqueous solution. The contact method is not particularly limited and examples thereof include an immersion method and a spraying method. Among these, the immersion method can be preferably used.

When the acid aqueous solution is used, an aqueous solution of an inorganic acid such as sulfuric acid, phosphoric acid, nitric acid or hydrochloric acid, or a mixture thereof is preferably used. Among these, an aqueous solution not containing chromic acid can be preferably used in terms of its high degree of safety. The concentration of the acid aqueous solution preferably ranges from 1 wt % to 10 wt %. The temperature of the acid aqueous solution preferably ranges from 25° C. to 60° C.

On the other hand, when the alkaline aqueous solution is used, an aqueous solution of at least one alkali selected from the group consisting of sodium hydroxide, potassium hydroxide, and lithium hydroxide is preferably used. The concentration of the alkaline aqueous solution preferably ranges from 0.1 wt % to 5 wt %. The temperature of the alkaline aqueous solution preferably ranges from 20° C. to 35° C.

Specific examples of solutions that may be preferably used include a 40° C. aqueous solution containing 50 g/L of phosphoric acid, a 30° C. aqueous solution containing 0.5 g/L of sodium hydroxide, and a 30° C. aqueous solution containing 0.5 g/L of potassium hydroxide.

The time of immersion in the acid aqueous solution or the alkaline aqueous solution preferably ranges from 8 minutes to 120 minutes, more preferably from 10 minutes to 90 minutes, and still more preferably from 15 minutes to 60 minutes.

By this trimming treatment, the heat dissipating portions 31 are formed in the anisotropically-conductive member 11, as shown in FIGS. 1A to 7.

For example, a method which involves exposing a part in which the heat dissipating portions 31 should be formed and masking the other part can be used to form the heat dissipating portions 31 in an arbitrary part of the anisotropically-conductive member 11. At this time, for example, a mask layer may be formed before the trimming treatment so as to expose the part in which the heat dissipating portions 31 should be formed and then the mask layer may be removed after the trimming treatment. The formation and removal of the mask layer can be performed in the same way as the mask layer forming step and the mask layer removing step.

### Method of Manufacturing Multi-Layered Board

Next, a method of manufacturing the multi-layered board according to the present invention will be described below in detail.

The multi-layered board according to the present invention can be manufactured, for example, using a manufacturing method including a mask layer forming step of forming a mask layer on at least one surface of the anisotropically-conductive member, a heat conducting layer forming step of forming a heat conducting layer, and a mask layer removing step of removing the mask layer to obtain a multi-layered board, in this order.

The heat conducting layer forming step will be specifically described below. The mask layer forming step and the mask layer removing step can be performed in the same way as described in the method of manufacturing the anisotropically-conductive member.

### Heat Conducting Layer Forming Step

The heat conducting layer forming step preferably has a heat conducting portion forming step, an interconnecting portion forming step, and an insulating portion forming step to be described later.

### Heat Conducting Portion Forming Step

The heat conducting portion forming step is a step of forming heat conducting portions on at least one surface of the anisotropically-conductive member.

Here, examples of the method of forming the heat conducting portions on at least one surface of the anisotropically-conductive member include various plating treatments such as electrolytic plating, electroless plating, and displacement plating; sputtering; and vapor deposition.

Among these, a layer is preferably formed of only a metal from the viewpoint of excellent heat resistance. A layer is most preferably formed using a plating treatment from the viewpoint of uniform formation of a thick layer and high adhesiveness.

Since the plating treatment is performed on a non-conductive material (anisotropically-conductive member), a technique of forming a reducing metal layer called a seed layer and then forming a thick metal layer using the reducing metal layer is preferably used.

The seed layer is preferably formed using a sputtering treatment. The electroless plating may also be used to form the seed layer, and as a plating solution to form the seed layer, a solution composed of main components (such as a metal salt and a reducing agent) and auxiliary components (such as a pH adjuster, a buffering agent, a complexing agent, a promoter, a stabilizer, and an improving agent) can be preferably used. Commercially-available products such as SE-650•666•680, SEK-670•797, and SFK-63 (made by JAPAN KANIGEN Co., Ltd.) and MELPLATE NI-4128, ENPLATE NI-433, and ENPLATE NI-411 (made by MELTEX Inc.) can be appropriately used for the plating solution.

When copper is used as the material of the heat conducting portions, various electrolytic solutions which contain sulfuric acid, copper sulfate, hydrochloric acid, polyethylene glycol, and a surfactant as main components and to which various other additives are added can be used.

### Interconnecting Portion Forming Step

The interconnecting portion forming step is a step of forming interconnecting portions on at least one surface of the anisotropically-conductive member.

Here, examples of the method of forming the interconnecting portions include various plating treatments such as electrolytic plating, electroless plating, and displacement plating; sputtering; and vapor deposition.

Among these, a layer is preferably formed of only a metal from the viewpoint of excellent heat resistance. A layer is most preferably formed by a plating treatment from the viewpoint of uniform formation of a thick layer and high adhesiveness.

Since the plating treatment is performed on a non-conductive material (anisotropically-conductive member), a technique of forming a reducing metal layer called a seed layer and then forming a thick metal layer using the reducing metal layer is preferably used.

The seed layer is preferably formed using a sputtering treatment. The electroless plating may also be used to form the seed layer, and as a plating solution to form the seed layer, a solution composed of main components (such as a metal salt and a reducing agent) and auxiliary components (such as a pH adjuster, a buffering agent, a complexing agent, a promoter, a stabilizer, and an improving agent) can be preferably used. Commercially-available products such as SE-650•666•680, SEK-670•797, and SFK-63 (made by JAPAN KANIGEN Co., Ltd.) and MELPLATE NI-4128, ENPLATE NI-433, and ENPLATE NI-411 (made by MELTEX Inc.) can be appropriately used for the plating solution.

When copper is used as the material of the interconnecting portions, various electrolytic solutions which contain sulfuric acid, copper sulfate, hydrochloric acid, polyethylene glycol, and a surfactant as main components and to which various other additives are added can be used.

The interconnecting portions formed in this way are shaped in a pattern using a known method depending on a mounting design for a semiconductor device or the like. A metal (also including a solder) can be provided again in a place on which the semiconductor device or the like is to be actually mounted and can be appropriately processed for easy connection by thermocompression bonding, flip-chip bonding, wire bonding, and the like.

Suitable examples of the metal include solder or metallic materials such as gold (Au), silver (Ag), copper (Cu), aluminum (Al), magnesium (Mg), and nickel (Ni). From the viewpoint of mounting of a semiconductor device by heating, soldering or a method of forming an Au or Ag film with Ni interposed therebetween can be preferably used in view of connection reliability.

Specifically, an example of the method of forming a gold (Au) film on a patterned copper (Cu) interconnection with nickel (Ni) interposed therebetween is a method of performing a Ni strike plating and then performing an Au plating.

Here, the Ni strike plating is performed for the purpose of removal of a surface oxide layer on the Cu interconnection and securing of adhesiveness of the Au layer.

In the Ni strike plating, a general Ni/hydrochloric acid mixture solution may be used, or a commercially-available product such as NIPS-100 (made by Hitachi Chemical Co., Ltd.) may be used.

On the other hand, the Au plating is performed for the purpose of improving the wettability in wire bonding or soldering after performing the NI strike plating.

The Au plating is preferably performed using electroless plating, and commercially-available treatment solutions such as HGS-5400 (made by Hitachi Chemical Co., Ltd.) and MICROFAB Au series, GALVANOMEISTER GB series, and PRECIOUSFAB IG series (all of which are made by Tanaka Holdings Co., Ltd.) can be used.

### Insulating Portion Forming Step

The insulating portion forming step is a step of forming the insulating portions.

The method of forming the insulating portions is not particularly limited, and when the above-mentioned resin is used for the insulating portions, examples thereof include a method of laminating the resin on the anisotropically-conductive member using a laminating machine, a method of coating the anisotropically-conductive member with the resin using a spin coater, and a method of forming the insulating portions using a flip-chip bonding machine at the same time as bonding the anisotropically-conductive member and the semiconductor device.

### Method of Manufacturing Semiconductor Package

The method of manufacturing the semiconductor package according to the present invention comprises a step of mounting the semiconductor device on at least one surface of the multi-layered board according to the present invention.

When the semiconductor device is mounted on the multi-layered board according to the present invention, mounting is performed by heating. In the mounting by thermocompression bonding including reflow soldering and the mounting by flip-chip bonding, the maximum temperature reached preferably ranges from 220° C. to 350° C., more preferably from 240° C. to 320° C., and still more preferably from 260° C. to 300° C., from the viewpoint of uniform and reliable mounting.

The time for maintaining the maximum temperature reached preferably ranges from 2 seconds to 10 minutes, more preferably from 5 seconds to 5 minutes, and still more preferably from 10 seconds to 3 minutes, from the same viewpoint as above.

From the viewpoint of suppression of cracks that may be generated in the anodized film due to a difference in coefficient of thermal expansion between the aluminum substrate and the anodized film, a method of performing heat treatment at a desired constant temperature for 5 seconds to 10 minutes, more preferably for 10 seconds to 5 minutes, and most preferably for 20 seconds to 3 minutes may be performed before reaching the maximum temperature. The desired constant temperature preferably ranges from 80° C. to 200° C., more preferably from 100° C. to 180° C., and most preferably from 120° C. to 160° C.

The temperature at the time of mounting by wire bonding preferably ranges from 80° C. to 300° C., more preferably from 90° C. to 250° C., and most preferably from 100° C. to 200° C., from the viewpoint of reliable mounting. The heating time preferably ranges from 2 seconds to 10 minutes, more preferably from 5 seconds to 5 minutes, and most preferably from 10 seconds to 3 minutes.

### EXAMPLES

The present invention will be specifically described with reference to examples. However, the present invention is not limited to the examples.

### Example 1

### Manufacturing of Anisotropically-Conductive Member Manufacturing of Aluminum Substrate

A molten metal was prepared using an aluminum alloy containing 0.06 wt % of Si, 0.30 wt % of Fe, 0.005 wt % of Cu, 0.001 wt % of Mn, 0.001 wt % of Mg, 0.001 wt % of Zn, 0.03 wt % of Ti, with the balance being Al and inevitable impurities. The molten metal was subjected to molten metal treatment and filtering, and then was cast into a 500 mm thick, 1,200 mm wide ingot by a direct chill casting process.

Subsequently, the ingot was scalped with a scalping machine, removing on average 10 mm of material from the surface, then soaked and held at 550° C. for about 5 hours. When the temperature had fallen to 400° C., the ingot was rolled with a hot rolling mill to a plate thickness of 2.7 mm.

In addition, heat treatment was carried out at 500° C. in a continuous annealing furnace, after which cold rolling was carried out to finish the aluminum plate to a thickness of 1.0 mm thereby obtaining a JIS 1050 aluminum substrate.

This aluminum substrate was cut into a width of 1030 mm and was subjected to electropolishing treatment described below.

### Electropolishing Treatment

The electropolishing treatment was performed on the aluminum substrate using an electropolishing solution having the following composition under the conditions of a voltage of 25 V, a solution temperature of 65° C., and a solution flow rate of 3.0 m/min.

A carbon electrode was used as a cathode and GP0110-30R (made by TAKASAGO LTD.) was used as a power supply. The flow velocity of the electrolytic solution was measured using a vortex flow monitor FLM 22-10 PCW (made by AS ONE Corporation).

### Composition of Electropolishing Solution

85 wt % of phosphoric acid (reagent made by Wako Pure Chemical Industries, Ltd.): 660 mL
Pure water: 160 mL
Sulfuric acid: 150 mL
Ethylene glycol: 30 mL

### Anodization

Subsequently, anodization using a self-ordering method was performed on the aluminum substrate subjected to the electropolishing treatment according to the procedure described in JP 2007-204802 A.

First, the aluminum substrate having undergone the electropolishing treatment was subjected to 5 hours of preliminary anodization with an electrolytic solution of 0.50 mol/L oxalic acid under the following conditions: voltage, 40 V; solution temperature, 16° C.; and solution flow velocity, 3.0 m/min.

After preliminary anodization, the aluminum substrate was subjected to film removal treatment in which it was immersed for 12 hours in a mixed aqueous solution (solution temperature, 50° C.) of 0.2 mol/L chromic anhydride and 0.6 mol/L phosphoric acid.

Next, the aluminum substrate was subjected to 16 hours of re-anodization with an electrolytic solution of 0.50 mol/L oxalic acid under the following conditions: voltage, 40 V; solution temperature, 16° C.; and solution flow velocity, 3.0 m/min. An anodized film having a thickness of 130 μm was thus obtained.

Preliminary anodization and re-anodization were both carried out using a stainless steel electrode as the cathode and using a GP0110-30R unit (Takasago, Ltd.) as the power supply. Use was made of NeoCool BD36 (Yamato Scientific Co., Ltd.) as the cooling system, and Pairstirrer PS-100 (Tokyo Rikakikai Co., Ltd.) as the stirring and warming unit. In addition, the flow velocity of the electrolytic solution was measured using the vortex flow monitor FLM22-10PCW (As One Corporation).

### Perforation Treatment

Next, the aluminum substrate was dissolved by 3 hours of immersion at 20° C. in a 20 wt % aqueous solution of mercuric chloride (corrosive sublimate). Then, the anodized film was immersed in 5 wt % phosphoric acid at 30° C. for 30 minutes to remove the bottom of the anodized film to thereby prepare an anodized film having through-holes.

The through-holes had an average pore size of 30 nm. The average pore size was obtained by taking a surface image by FE-SEM (S-4800, made by Hitachi, Ltd.) at a magnification of 50,000×, measuring the pore size at 50 points and calculating the average of the measurements.

The average depth of the through-holes was 130 μm. Here, the average depth was determined by cutting the resulting anodized film in the thickness direction of the through-holes with FIB, taking an image of the cross-sectional surface by FE-SEM (S-4800, made by Hitachi, Ltd.) at a magnification of 50,000×, measuring the through-hole depth at 10 points and calculating the average of the measurements.

The density of the through-holes was about 100,000,000 pieces/mm². Here, the density was calculated using the method described in paragraph [0151] of JP 2012-089481 A.

The degree of ordering of the through-holes was 92%. Here, a surface image (magnification: 20,000×) was taken by FE-SEM (S-4800, made by Hitachi, Ltd.), and the degree of ordering of the through-holes, as defined by the above-mentioned Expression (i), was measured with a field of view of 2 μm×2 μm.

### Heating Treatment

Then, the anodized film obtained as above was heated at a temperature of 400° C. for 1 hour.

### Electrode Film Formation

Subsequently, a treatment was carried out for forming an electrode film on one surface of the anodized film having undergone the above-described heating treatment. To be more specific, an aqueous solution of 0.7 g/L chloroauric acid was applied to one surface, dried at 140° C. for 1 minute and further baked at 500° C. for 1 hour to form plating nuclei of gold. Then, PRECIOUSFAB ACG2000 base solution/reducing solution (available from Electroplating Engineers of Japan Ltd.) was used as the electroless plating solution to carry out immersion at 50° C. for 1 hour to thereby form the electrode film having no void.

Electrolytic Plating (Filling with Metal)

Subsequently, a copper electrode was placed in close contact with the surface of the formed electrode film, and electrolytic plating was carried out using the copper electrode as the cathode and platinum as the anode.

In Example 1, the copper plating solution of the composition indicated below was used to carry out constant current electrolysis to thereby prepare an anisotropically-conductive member in which the through-holes were filled with copper.

After the deposition potential was checked by cyclic voltammetry in the plating solution, constant current electrolysis was carried out under the following conditions using an electroplating system manufactured by Yamamoto-MS Co., Ltd. and a power supply (HZ-3000) manufactured by Hokuto Denko Corp.

### Composition of Copper Plating Solution

Copper sulfate: 100 g/L
Sulfuric acid: 50 g/L
Hydrochloric acid: 15 g/L

### Conditions of Constant-Current Electrolysis

Temperature: 25° C.
Current density: 10 A/dm²

### Polishing Treatment

Subsequently, both the surfaces of the prepared anisotropically-conductive member were subjected to mechanical polishing and the anisotropically-conductive member resulting therefrom had a thickness of 110 μm.

Here, a ceramic jig (Kemet Japan Co., Ltd.) was used for the sample holder in mechanical polishing and ALCOWAX (Nikka Seiko Co., Ltd.) was used as a material applied to the sample holder. DP-Suspensions P-6 μm·3 μm·1 μm·¼ μm (available from Struers) were used in order for the abrasive.

The sealing rate of the through-holes of the prepared anisotropically-conductive member filled with metal was measured. More specifically, both the surfaces of the prepared anisotropically-conductive member were observed by FE-SEM (S-4800 made by Hitachi, Ltd.) to see whether or not 1,000 through-holes were sealed, thereby calculating the sealing ratio on both the surfaces, and the average was determined therefrom. As a result, the sealing rate of the anisotropically-conductive member in Example 1 was 96%.

The thus prepared anisotropically-conductive member was cut by FIB in the thickness direction, a cross-sectional image was taken by FE-SEM (S-4800 made by Hitachi, Ltd.) at a magnification of 50,000× and the interiors of the through-holes were checked. As a result, it was revealed that the interiors of the sealed through-holes were completely filled with metal.

### Trimming Treatment (Formation of Heat Dissipating Portion)

Subsequently, the anisotropically-conductive member subjected to the polishing treatment was masked and immersed in a phosphoric acid solution to selectively dissolve the anodized film, whereby metal cylinders serving as the conduction passages were made to protrude to form the heat dissipating portions.

The same solution as in the perforation treatment was used as the phosphoric acid solution and the treatment time in Example 1 was set to 18 minutes. The treatment time in Examples 2, 3, 5, and 6 to be described later was set to 20 minutes and the treatment time in Example 4 was set to 25 minutes.

### Manufacturing of Multi-layered Board (Formation of Heat Conducting Portion)

### Formation of Mask Layer

The surface of the anisotropically-conductive member was coated with a photoresist (FC-230G made by TOYOBO Co., Ltd.) and was irradiated with UV rays via a mask so as to give a predetermined opening pattern thereto.

Thereafter, the non-irradiated portion was completely removed by development using an alkaline developer and the surface of the anisotropically-conductive member was exposed in a pattern shape.

In Examples 1 to 4, the pattern of the heat conducting portions and the pattern of the interconnecting portions were formed at the same time.

### Formation of Heat Conducting Portion and Interconnecting Portion

A seed layer was formed through Au sputtering and then the heat conducting portions and the interconnecting portions with a thickness of 5 μm were formed by electrolytic copper plating.

### Removal of Mask Layer

The mask layer was removed from the anisotropically-conductive member having the mask layer formed thereon using a monomethanolamine solvent, whereby a multi-layered board according to Example 1 as shown in FIGS. 1A to 1C was manufactured.

### Example 2

By performing formation of a mask layer of a heat conducting portion pattern, formation of a diamond-like carbon (DLC) film, and removal of the mask layer in this order after the trimming treatment in Example 1 (where the treatment time was set to 20 minutes), the DLC film was formed as the heat conducting portions of the heat conducting layer. The DLC film was formed using a DLC film forming apparatus and an ionized deposition method.

Thereafter, by forming only the interconnecting portions of the heat conducting layer in the same way as in Example 1 (formation of a mask layer, formation of interconnection portions, and removal of the mask layer), a multi-layered board according to Example 2 as shown in FIGS. 1A to 1C was manufactured.

### Example 3

A multi-layered board as shown in FIGS. 3A and 3B was manufactured in the same way as in Example 1, except that the heat conducting layer was formed on both surfaces of the anisotropically-conductive member. Here, the treatment time of the trimming treatment was set to 20 minutes.

### Example 4

A multi-layered board according to Example 4 as shown in FIG. 7 was manufactured by aligning the upper and lower interconnection patterns with each other when stacking the multi-layered board according to Example 3 (where the treatment time of the trimming treatment was set to 25 minutes), injecting and infiltrating an underfill agent ThreeBond 2274B made by ThreeBond Co., Ltd. from the lateral sides, and curing the underfill agent under thermosetting conditions of 85° C. for 45 minutes.

### Example 5

Recesses with a depth of 10 μm were formed by performing formation of a mask layer of a heat conducting portion pattern, formation of the recesses by etching, and removal of the mask layer in this order after the anodization in Example 1, the recesses were filled with a metal by performing up to the formation of the heat conducting layer in the same way as in Example 1, and then a multi-layered board according to Example 5 as shown in FIG. 4 was manufactured by forming only the interconnecting portions of the heat conducting layer in the same way as in Example 1 (formation of a mask layer, formation of interconnection portions, and removal of the mask layer). Here, the treatment time of the trimming treatment was set to 20 minutes.

### Example 6

DLC film was formed in recesses with a depth of 10 μm by performing formation of a mask layer of a heat conducting portion pattern, formation of the recesses by etching, formation of the DLC film, and removal of the mask layer in this order after the trimming treatment in Example 1, and then only the interconnecting portions of the heat conducting layer were formed in the same way as in Example 1 (formation of a mask layer, formation of interconnection portions, and removal of the mask layer) to manufacture a multi-layered board according to Example 6 as shown in FIG. 4. Here, the treatment time of the trimming treatment was set to 20 minutes. The same method as in Example 2 was used to form the DLC film.

### Comparative Example 1

A multi-layered board was manufactured in the same way as in Example 1, except that the heat conducting portion pattern was not formed in formation of the heat conducting layer and the heat dissipating portions were not formed by the trimming treatment. In Comparative Example 1, the items of “heat conducting layer” and “heat conducting portion” in Table 1 were marked by “-.”

### Evaluation

### Heat Dissipating Portion

### Calculation of Height of Heat Dissipating Portion

Regarding the height of the heat dissipating portions in each of the manufactured multi-layered boards, nine positions including four positions on four sides of the plane and five positions therebetween were observed from the cross-sectional direction using FE-SEM (S-4800 made by Hitachi, Ltd.), the height at each position was calculated from the average measured value of 10 points, and the heights at the nine positions were averaged. The results are shown in Table 1. For Comparative Example 1 in which the heat dissipating portions were not formed, the height of heat dissipating portion was marked by “-” (the same applies for the area).

### Calculation of Area of Heat Dissipating Portion

The area of the heat dissipating portions was calculated as a ratio to the area of the semiconductor device (to be described later) disposed on the multi-layered board. The results are shown in Table 1.

### Heat Conducting Layer (Heat Conducting Portion)

### Calculation of Thickness of Heat Conducting Portion

Regarding the thickness of the heat conducting portions of the heat conducting layer in each of the manufactured multi-layered boards, nine positions including four positions on four sides of the plane and five positions therebetween were observed from the cross-sectional direction using FE-SEM (S-4800 made by Hitachi, Ltd.), the thickness at each position was calculated from the average measured value of 10 points, and the thicknesses at the nine positions were averaged. The results are shown in Table 1. For Comparative Example 1 in which the heat conducting portions were not formed, the average thickness was marked by “-” (the same applies for the area).

### Calculation of Area of Heat Conducting Portion

The area of the heat conducting portions of the heat conducting layer in the multi-layered board was calculated as a ratio to the area of the semiconductor device disposed on the multi-layered board. The results are shown in Table 1.

### Manufacturing of Semiconductor Package

### Semiconductor Device (TEG Chip)

First, a test element group (TEG) was manufactured as a semiconductor device. Resistive elements in the TEG chip were designed to serve as a heat source and diodes therein were designed to serve as a temperature sensor.

### Mounting of TEG Chip and Formation of Insulating Portion

The TEG chips were arranged on the top and bottom of the multi-layered board so that the interconnection patterns are aligned with each other, an underfill agent ThreeBond 2274B made by ThreeBond Co., Ltd. was injected and infiltrated from the lateral sides of the layers including the multi-layered board and the TEG chips, and the underfill agent was cured under thermosetting conditions of 85° C. for 45 minutes, whereby the interconnection layer and the TEG chips were connected to each other.

### Drive Test

The TEG chips were driven, and at a point at which the power consumption of the TEG chips reached 500 mW, the junction temperature and the package surface temperature were measured. The results are shown in Table 1.

The forward diode voltage of the TEG chip was measured and the junction temperature was calculated from the temperature dependency thereof.

TABLE 1

| | | | | Height of | Area of | Thickness | Area of | | |
|---|---|---|---|---|---|---|---|---|---|
| | | Material | | heat | heat | of heat | heat | | |
| | Heat | of heat | | dissipating | dissipating | conducting | conducting | Junction | Package |
| | conducting | conducting | Filler | portion | portion | portion | portion | temperature | temperature |
| | layer | portion | metal | [μm] | [%] | [μm] | [%] | [° C.] | [° C.] |
| Ex. 1 | one | Cu | Cu | 35 | 50 | 5 | 50 | 86 | 106 |
| | surface/one | | | | | | | | |
| | layer/surface | | | | | | | | |
| Ex. 2 | one | DLC | Cu | 40 | 50 | 5 | 50 | 73 | 90 |
| | surface/one | | | | | | | | |
| | layer/surface | | | | | | | | |
| Ex. 3 | both | Cu | Cu | 40 | 50 | 5 | 50 | 72 | 88 |
| | surfaces/two | | | | | | | | |
| | layers/surface | | | | | | | | |
| Ex. 4 | both | Cu | Cu | 50 | 50 | 5 | 50 | 61 | 76 |
| | surfaces/three | | | | | | | | |
| | layers/surface | | | | | | | | |
| Ex. 5 | one | Cu | Cu | 40 | 50 | 10 | 50 | 72 | 93 |
| | surface/one | | | | | | | | |
| | layer/embedded | | | | | | | | |
| Ex. 6 | one | DLC | Cu | 40 | 50 | 10 | 50 | 63 | 80 |
| | surface/one | | | | | | | | |
| | layer/embedded | | | | | | | | |
| Com. | — | — | Cu | — | — | — | — | 125 | 160 |
| Ex. 1 | | | | | | | | | |

From the measurement result of the junction temperature, it could be seen that the heat conductivity was improved in the examples more than Comparative Example 1.

In addition, it could be seen that the junction temperature was lowered and the difference between the package surface temperature and the junction temperature was decreased by forming the heat dissipating portions. This represents that the performance of heat dissipation from the package surface was improved.

What is claimed is:

1. A multi-layered board comprising:
an anisotropically-conductive member that comprises an insulating base which is an anodized film of an aluminum substrate and in which through-holes are formed in a thickness direction and a plurality of conduction passages which are formed of a conductive material filled in the through-holes and which extend through the insulating base in the thickness direction with the conduction passages insulated from each other;
a heat conducting layer that comprises heat conducting portions and is disposed on at least one surface of the anisotropically-conductive member; and
heat dissipating portions formed of the conductive material and protruding from the insulating base.

2. The multi-layered board according to claim 1, wherein the heat conducting layer comprises the heat conducting portions, interconnecting portions formed of a conductive material, and insulating portions insulating the heat conducting portions and the interconnecting portions from each other.

3. The multi-layered board according to claim 2, wherein the insulating portions are formed of a resin.

4. The multi-layered board according to claim 1, wherein the heat dissipating portions protruding from the anodized film have a height of 35 μm or more.

5. The multi-layered board according to claim 1, wherein the heat conducting portions are embedded in the anodized film.

6. The multi-layered board according to claim 1, wherein the heat conducting layer is disposed between two or more anisotropically-conductive members.

7. A semiconductor package comprising:
the multi-layered board according to claim 1; and
a semiconductor device that is disposed on at least one surface of the multi-layered board.

8. The multi-layered board according to claim 2, wherein the heat dissipating portions protruding from the anodized film have a height of 35 μm or more.

9. The multi-layered board according to claim 2, wherein the heat conducting portions are embedded in the anodized film.

10. The multi-layered board according to claim 4, wherein the heat conducting portions are embedded in the anodized film.

11. The multi-layered board according to claim 8, wherein the heat conducting portions are embedded in the anodized film.

12. The multi-layered board according to claim 2, wherein the heat conducting layer is disposed between two or more anisotropically-conductive members.

13. The multi-layered board according to claim 4, wherein the heat conducting layer is disposed between two or more anisotropically-conductive members.

14. The multi-layered board according to claim 5, wherein the heat conducting layer is disposed between two or more anisotropically-conductive members.

15. The multi-layered board according to claim 8, wherein the heat conducting layer is disposed between two or more anisotropically-conductive members.

16. The multi-layered board according to claim 9, wherein the heat conducting layer is disposed between two or more anisotropically-conductive members.

17. The multi-layered board according to claim 10, wherein the heat conducting layer is disposed between two or more anisotropically-conductive members.

18. The multi-layered board according to claim 11, wherein the heat conducting layer is disposed between two or more anisotropically-conductive members.

19. The multi-layered board according to claim 11, wherein the insulating portions are formed of a resin.

20. The multi-layered board according to claim 18, wherein the insulating portions are formed of a resin.
